(19) United States
(12) Patent Application Publication
(10) Pub. No.: US 2006/0255996 A1
(43) Pub. Date: Nov. 16, 2006

(54) Baseband signal processor

(75) Inventors: Chin Li, Murray Hill, NY (US); Paul B. Sheehy, Easton, PA (US); Eoin Carey, Cork (IE); Gerard Quilligan, Gulf Breeze, FL (US); Walid Khairy Mohamed Ahmed, Tinton Falls, NJ (US)

Correspondence Address: Tyco Electronics Corporation, Suite 140, 4550 New Linden Hill Road, Wilmington, DE, 19808-2952, US

(73) Assignee: M/A-COM, Inc. and M/A-Com Eurotec BV

(21) Appl. No.: 11/398,060

(22) Filed: Apr. 4, 2006

Related U.S. Application Data
(60) Provisional application No. 60/669,825, filed on Apr. 8, 2005.

(51) Int. Cl. H03M 1/12

(52) U.S. Cl. 341/156

(57) ABSTRACT

A power control module receives a dynamic power control signal and generates a differential bias signal proportional to the dynamic power control signal. An analog multiplexer receives a digital amplitude signal including n bits and receives the differential bias signal. The analog multiplexer multiplexes the digital amplitude signal with the differential bias signal in parallel and generates a first differential signal. A driver module receives the first differential signal and a second differential signal. The driver module generates a first drive signal proportional to the dynamic power control signal when a bit in said digital amplitude signal is a logic one and the driver module generates a second drive signal proportional to the second differential signal when a bit in said digital amplitude signal is a logic zero.

### RELATED APPLICATION

This application claims the benefit of U.S. Provisional Patent Application Ser. No. 60/669,825 titled “Analog Baseband Signal Processor” filed Apr. 8, 2005, which is incorporated herein by reference in its entirety.

This application is related to commonly assigned U.S. application Ser. No. ______ titled “Differential Analog Filter” filed concurrently herewith.

### BACKGROUND

Telecommunications transmitter systems often employ a digital radio frequency (RF) power amplifier (PA). Due to the digital processing nature, signals processed by the digital RF PAs may contain some level of inherent quantization noise. Quantization noise is a noise error introduced by the analog-to-digital conversion process in telecommunication and signal processing systems. Quantization noise is a rounding error between the analog input voltage to the analog-to-digital converter and the digitized output value. The quantization noise is generally non-linear and signal-dependent.

Telecommunications transmitter systems may include a polar digital RF PA comprising an RF digital-to-analog converter (RF-DAC). Herein, a digital RF PA is referred to as an RF-DAC. The inherent quantization noise may degrade the performance of the RF-DAC, particularly quantization noise may “contaminate” the receive band spectrum of a CDMA system due to the sin (x)/x profile of a sample and hold system, such as RFDAC. Therefore, to minimize performance degradation due to quantization noise, a polar digital RF PA may require some form of signal processing and/or filtering to suppress the quantization noise at the receive band.

A polar digital RF PA splits baseband input signals into separate amplitude and phase signal components. The separate signal components are processed in separate amplitude and phase signal paths. The amplitude and phase signal components in each path may include some noise error. For example, quantization noise may be present in the amplitude signal path and phase jitter noise may be present in the phase signal path. These noise components may significantly affect the overall performance of the polar digital RF PA.

Accordingly, in various telecommunications applications, signal processing and/or filtering the quantization noise in the amplitude signal path may be desirable to comply with the strict noise requirements at the receive band. For example, in digital wireless telephony transmission techniques, such as Code Division Multiple Access 2000 (CDMA-2000), receive band noise requirements are stringent. Therefore, to comply with such stringent CDMA-2000 receive band noise requirements, the amplitude quantization noise and the phase jitter noise may require filtering or processing to reduce the overall noise level, for example. The amplitude quantization noise and the phase jitter noise branches of noise are additive. Therefore, they may be individually suppressed and recombined at the output of the RF-DAC, for example.

Accordingly, there may be a need for various techniques to minimize or suppress the quantization noise in the amplitude signal path of a polar digital RF PA. There may be a need to minimize or suppress the quantization noise by filtering at the transmitter. There may be a need to minimize or suppress the quantization noise by filtering prior to the amplifier PA stage of the transmitter.

### SUMMARY

In one embodiment, a baseband processor comprises a power control module to receive a dynamic power control signal and to generate a differential bias signal proportional to the dynamic power control signal. An analog multiplexer receives a digital amplitude signal comprising n bits and receives the differential bias signal. The analog multiplexer multiplexes the digital amplitude signal with the differential bias signal in parallel to generate a first differential signal. A driver module receives the first differential signal and receives a second differential signal. The driver module generates a first drive signal proportional to the dynamic power control signal when a bit in the digital amplitude signal is a logic one and the driver module generates a second drive signal proportional to the second differential signal when a bit in the digital amplitude signal is a logic zero.

In one embodiment, a polar modulation transmitter system comprises an amplifier comprising at least a first and second transistor. The first and second transistors are formed on the same substrate and have similar current gains (β). A baseband processor dynamically biases a driver module coupled to the amplifier. The baseband processor comprises a power control module to receive a dynamic power control signal and to generate a differential bias signal proportional to the dynamic power control signal. An analog multiplexer receives a digital amplitude signal comprising n bits and receives the differential bias signal. The analog multiplexer multiplexes the digital amplitude signal with the differential bias signal in parallel to generate a first differential signal. The driver module is coupled to at the least first transistor. The driver module receives the first differential signal and to receive a second differential signal. The driver module generates a first drive signal to drive the at least first transistor, the first drive signal is proportional to the dynamic power control signal, when a bit in the digital amplitude signal is a logic one. The driver module generates a second drive signal to drive the at least first transistor, the second drive signal proportional to the second differential signal, when a bit in the digital amplitude signal is a logic zero.

In one embodiment, a method to dynamically bias a driver for power control and offset control includes receiving a dynamic power control signal; generating a differential bias signal proportional to the dynamic power control signal; receiving a digital amplitude signal; multiplexing the differential bias signal with the digital amplitude signal in parallel; and generating a first drive signal proportional to the dynamic power control signal when a bit in the digital amplitude signal is a logic one and generating a second drive signal proportional to the second differential signal when a bit in the digital amplitude signal is a logic zero.

### BRIEF DESCRIPTION OF THE DRAWINGS

FIG. 1 illustrates one embodiment of a baseband signal processor system.

FIG. 2A illustrates one embodiment of a baseband signal processor system.

FIG. 2B illustrates one embodiment of a radio frequency digital-to-analog converter (RF-DAC).

FIG. 3 illustrates one embodiment of a driver portion of the systems discussed above with reference to FIGS. 1 and 2.

FIG. 4 illustrates one embodiment of a system illustrating process variation and Gₘ control.

FIGS. 5A, B illustrate embodiments of dynamic biasing diagrams for power control and minimal current control in fixed biasing implementations.

FIGS. 6A, B illustrate embodiments of dynamic biasing diagrams for power control and minimal current control for dynamic biasing implementations.

FIGS. 7A, B illustrate embodiments of dynamic biasing diagrams for power control and minimal current control for offset or trickle control biasing implementations.

FIG. 8A is a diagram illustrating one embodiment of a post RF-DAC band pass filter implementation.

FIG. 8B is a diagram illustrating one embodiment a pre RF-DAC low pass filter implementation.

FIG. 9A illustrates one embodiment of a filter comprising a fully differential topology.

FIG. 9B illustrates one embodiment of the filter comprising a fully differential topology shown in FIG. 9A.

FIG. 10 illustrates one embodiment of a fully differential amplifier operational amplifier.

FIGS. 11A, 11B, and 11C illustrate embodiments of trimmable resistor modules.

FIG. 11D illustrates one embodiment of a precision voltage reference used to generate the reference voltages V_{ref}-1-p for the trimmable resistor modules illustrated in FIGS. 11A, 11B, and 11C.

FIG. 12 illustrates one embodiment of a polar modulation power transmitter system comprising one embodiment of the baseband processor in relative relationship to the rest of the polar transmitter system.

FIGS. 13A, 13B illustrate quantization noise associated with a sample-and-hold system and its signal spectrum including the noise at the receive band spectrum.

FIG. 14 graphically illustrates measurement result waveforms comprising a first waveform and a second waveform measured at the output of one embodiment of the system baseband processor wherein the amplitude ratio between a first and second waveform illustrates the power control dynamic range.

FIG. 15 graphically illustrates a measured frequency response waveform of one embodiment of the Bessel filter implementation.

FIG. 16 illustrates one embodiment of a method to dynamically bias a driver for power control and offset control.

FIG. 17 illustrates one embodiment of a method to filter a differential analog signal.

### DETAILED DESCRIPTION

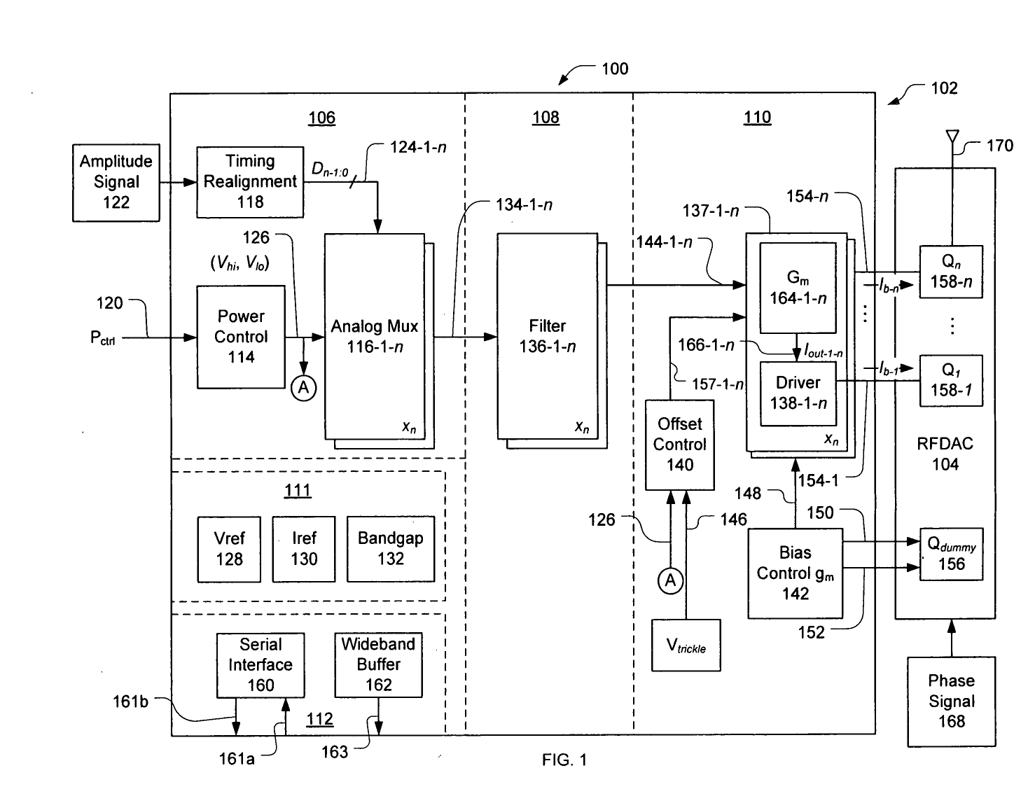

FIGS. 1-3 illustrate various embodiments of a baseband processor and the associated system architecture. In operation, the baseband processor reduces quantization noise associated with digital amplitude modulated signals. The baseband processor comprise a differential signal processing structure (topology) to process baseband amplitude modulated signals to reduce noise at the receive band spectrum of a receiver. In one embodiment, a differential signal processing topology may be employed to implement a low pass filter function.

The baseband processor circuit receives inputs from a baseband integrated circuit module. The baseband processor receives single-ended amplitude input signals from a digital signal processor module such as, for example, a coordinate rotation digital computer (CORDIC) algorithm module. The baseband processor converts the single ended input signals into differential signals. The output of the baseband processor is provided to a RF-DAC. Radio-frequency power amplifiers RF-PAs or RF-DACs may comprise single-ended topologies and may be capable of processing only single-ended signals. Therefore, the baseband processor may comprise RF-DAC drivers to convert the differential signals into single-ended signals compatible with the RF-DAC single-ended input structure. Furthermore, the baseband processor processes differential signals as voltages. The drivers, however, expect single-ended currents. Thus, the differential voltage signals are converted into single-ended currents prior to coupling to the RF-DAC.

Pre-driver circuitry may be employed to provide positive or negative “trickle” currents or bias currents to the drivers in addition to the main differential signals. A trickle current is a small amount of controllable current driven into the bases of the RF-DAC input transistors in addition to the current that is proportional to the main differential signals. This small amount of trickle current shifts the offset current signals into the RF-DAC by a positive or negative amount.

In one embodiment, the drivers may comprise CMOS components and the RF-DAC input transistors may be implemented with hetero-junction bipolar transistor (HBT) devices characterized by β amplification factor. The CMOS drivers may provide adjustment signals to the RF-DAC HBT devices to compensate for process temperature and supply (PTS) variations in the CMOS semiconductor fabrication process. This compensation may be required where the drivers operate in an open loop configuration. A biasing scheme compensates for some of the CMOS process variations such that the transconductance of the CMOS driver transistors are a function only of the threshold voltage of the CMOS transistors, for example. Accordingly, the drivers provide an output current that is proportional to the inverse of the beta (β) of the HBT devices. This β compensation enables the collector current of the HBT devices to be substantially independent of variations in β.

The baseband processor may comprise power control, filter, pre-driver, and driver functional modules, among others. The filter may be a low pass filter. In one embodiment, the filter may be a third-order low pass filter. In one embodiment, the filter may be a Bessel filter. In one embodiment, the filter may be a third-order low pass Bessel filter. In one embodiment, the filter module may comprise multiple third order Bessel low pass filters coupled to a trimmable resistor module. In one embodiment, the filter module may comprise a fully differential active RC third order Bessel filter, for example. In one embodiment, the pre-driver module may comprise a differential amplifier coupled to a differential voltage to single ended current transconductance Gₘ module. The driver module may comprise P-channel metal oxide semiconductor (PMOS) drivers. The driver module also may comprise a Vₜᵤₙₑ generator and 1/β generator. The driver module is coupled to the RF-DAC. These various embodiments are described herein below.

In one embodiment, a baseband processor comprises a power control module, an analog multiplexer of n bits, to receive a dynamic power control signal and n bit digital amplitude modulation signals to generate n corresponding bit analog amplitude modulation signals whose strength are proportional to the dynamic power control signal. The analog multiplexer multiplexes the digital amplitude signal with the voltage levels that are controlled by the power control signal to generate n bit analog differential signals. A driver module receives the n differential signals and also receives another differential signal used to dynamically bias the driver such that when a bit in the digital amplitude signal is logic zero, the correspond driver produces near zero or trickle amount of current and the trickle current can be adjusted through an on board DAC. The driver module generates a drive signal proportional to the dynamic power control signal when a bit in the digital amplitude signal is a logic one and the driver module generates another drive signal proportional to the differential signal to dynamically bias the driver when a bit in the digital amplitude signal is a logic zero.

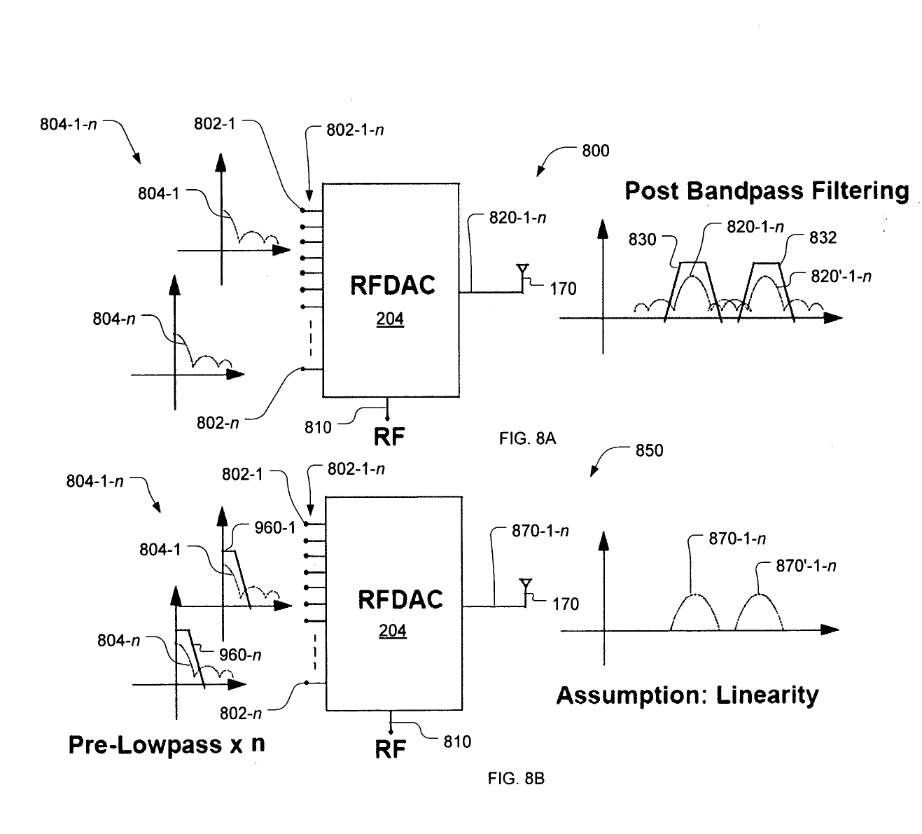

FIG. 1 illustrates one embodiment of a baseband signal processor system 100. The system 100 may comprise an analog baseband signal processor module 102 (baseband processor) coupled to a RF PA or RF-DAC 104. The baseband processor 102 receives digital amplitude baseband signals 122 comprising n bits at a first input. The baseband processor 102 outputs single-ended drive current signals 154-1-n (I_{b1-n}) to the various input transistors 158-1-n (Q₁₋ₙ) of the RF-DAC 104. In one embodiment, the single-ended drive current signals 154-1-n (I_{b1-n}) are segment drive currents to drive a segmented RF PA. In one embodiment, the RF-DAC 104 is a segmented RF PA comprising n segments. The baseband processor 102 reduces quantization noise inherent in the digital RF-DAC. As previously discussed, the quantization noise is noise error introduced by the analog-to-digital conversion process and other signal processing in telecommunication circuits. A significant amount of quantization noise may be present in the digital amplitude baseband signals 122. Similarly, a significant amount of phase jitter noise may be present in a phase signal 168. To comply with increasingly stringent receive band noise requirement in polar transmitter applications (e.g., CDMA-2000 applications) the amplitude and phase baseband signals 122, 168 may be filtered by the baseband processor 102 prior to the RF-DAC to remove or minimize the quantization noise. The quantization noise components in the amplitude and phase baseband signals 122, 168 branches are additive. Therefore, the noise in each branch may be individually filtered prior to the RF-DAC 104 and recombined at the RF-DAC 104 if the RF-DAC 104 is substantially linear. In one embodiment, the quantization noise may be filtered at the output of the RF-DAC 104. Band pass filtering after (post band pass filtering) the RF-DAC 104 and low pass filtering (pre-low pass filtering) prior to the RF-DAC 104 are illustrated below in FIGS. 8A and 8B.

In one embodiment, the baseband processor 102 may comprise a power control portion 106, a filter portion 108, a driver portion 110, a reference portion 111, and/or an interface portion 112. The baseband processor 102 receives digital amplitude baseband signals 122. The power control portion 106 assigns voltage levels to the digital amplitude baseband signals 122. The signals are filtered at the filter portion 108 and are converted from voltage signals to current signals by the driver portion 110. The driver portion 110 outputs single-ended drive current signals 154-1-n into the inputs of the RF-DAC 104 input transistors 158-1-n. The driver portion 110 interfaces the processed digital amplitude baseband signals 122 and the RF-DAC 104.

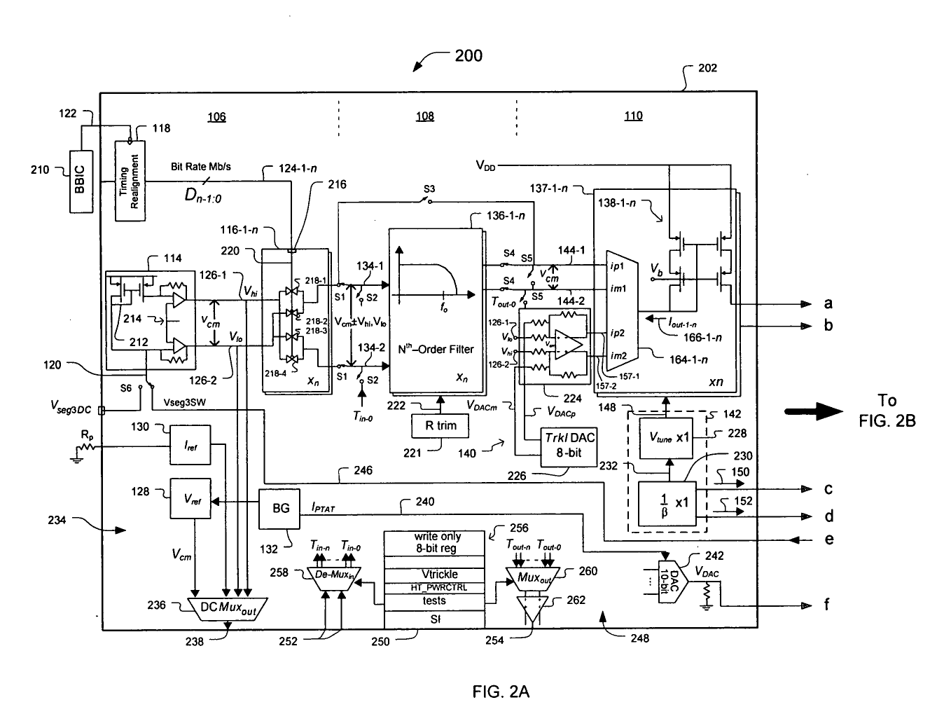

The baseband processor 102 receives the n-bit digital amplitude baseband signals 122 from external digital signal processing circuits. For example, in one embodiment, a baseband integrated circuit module 210 (see FIG. 2) provides the n-bit digital amplitude baseband signals 122 to the baseband processor 102. In one embodiment, the baseband integrated circuit module 210 may be, for example, a CORDIC. A CORDIC is an algorithm to calculate hyperbolic and trigonometric functions without a hardware multiplier using, for example, a microprocessor, microcontroller, a field programmable gate array (FPGA), or other processing device. In general, the CORDIC algorithm utilizes small lookup tables, performs bit-shifts, and additions, for example. Software or dedicated hardware implemented CORDIC algorithms may be suitable for pipelining.

In one embodiment, the most significant bits of the n-bit digital amplitude baseband signals 122 may be thermometer coded. In one embodiment, each of the digital amplitude baseband signals 122 may comprise n (e.g., n=11) forming n separate digital signals D_{n-1:0} where one or more of the most significant bits (e.g., the first three most significant bits) may be thermometer coded. Those skilled in the art will appreciate that in a thermometer code the number of ones (1s) (or alternatively, the number of zeros (0s)) in the converted signal represents the decimal value. A thermometer coded DAC minimizes the number of glitches (e.g., quantization noise) as compared to other DAC approaches. The embodiments are not limited in this context.

In one embodiment, the power control portion 106 may comprise a power control module 114, an analog multiplexer 116 coupled to the power control module 114, and a timing realignment module 118 coupled to the analog multiplexer 116. The baseband processor 102 receives a power control signal 120 at a second input. The power control signal 120 (P_{ctrl}) sets the voltage output at the power control module 114. The power control signal may vary in real-time or otherwise. This variation of the power control signal 120 is referred to as a dynamic variation. As the power control signal 120 varies dynamically, the biasing of the RF-DAC drivers also should vary dynamically. Accordingly, the term dynamic biasing may be used herein to refer to the variation of bias voltages to the RF-DCA drivers corresponding to the variation of the power control signal 120 at the input of the baseband processor signal processor module 102. The baseband processor 102 converts the n-bit digital amplitude baseband signals 122 from single-ended signals to double ended differential signals for processing in the differential topology of the baseband processor 102. For example, the timing realignment module 118 receives the single ended n-bit digital amplitude baseband signals 122 at a predetermined rate and outputs n-bit digital segment control signals 124-1-n (D_{n-1:0}) at a predetermined rate. Latches within the timing realignment module 118 realign the digital amplitude baseband signals 122 to remove or minimize timing skews that may result in glitches at the output of the RF-DAC 104 and increase the noise error in the system 100. The n-bit digital segment control signals 124-1-n (D_{n-1:0}) are processed in parallel at the predetermined rate.

The n-bit digital segment control signals 124-1-n from the timing realignment module 118 are provided to n analog multiplexers 116-1-n arranged in parallel. The analog multiplexers 116-1-n receive the time aligned digital voltage segment control signals 124-1-n from the timing realignment module 118. In one embodiment, each of the n analog multiplexers 116-1-n may be implemented as n 1-bit DACs, for example. The analog multiplexers 116-1-n multiplex the n-bit digital voltage segment control signals 124-1-n with differential bias voltage signals 126 comprising complementary first and second analog voltage levels Vₕᵢ and Vₗₒ provided by the power control module 114 and proportional to the power control signal 120. The differential bias voltage signals 126 (Vₕᵢ, Vₗₒ) may be superimposed on a common mode voltage V_{cm}. The multiplexers 116-1-n translate the n-bit digital voltage segment control signals 124-1-n swing between zero and fixed supply voltage into differential voltage signal 134 comprising n pairs of voltage signals 134-1-n, 134-2-n at variable voltage levels controlled by the power control signal 120. The power control module 114A may impress a common mode reference voltage V_{cm} at the input of the multiplexers 116-1-n. In one embodiment, the differential bias voltage signals 126 are superimposed on the common mode reference voltage V_{cm}. The power control module 114 provides the differential bias voltage signals 126 to the analog multiplexers 116-1-n at a predetermined bit rate. In one embodiment, for example, the bit rate of the digital voltage segment control signals 124-1-n may be approximately 9.8304 Mb/s.

In one embodiment, the system 100 power control may be achieved by adjusting the amplitude of the voltage signals 134-1-n at the input of the filter 136. At maximum power, for example, the amplitude of the amplitude baseband signal 134 may be approximately 300 mV, single-ended. In embodiments where the amplitude baseband signal 122 comprises n bits, the power control portion 106 translates the n digital amplitude bits into n pairs of differential analog signal levels and produces the time aligned digital voltage segment control signals 124-1-n. The time aligned digital voltage segment control signals 124-1-n are provided to the analog multiplexers 116-1-n and the power level of each of the signals 124-1-n are controlled by the power control signal 120. The analog multiplexers 116-1-n apply a common voltage V_{cm} to each individual bit of the time aligned digital segment control signals 124-1-n. In addition, the analog multiplexers 116-1-n multiplex the differential bias voltage signals 126 above and below the common mode voltage V_{cm}.

In one embodiment, the filter portion 108 may comprise a filter 136 to reduce the quantization and “sin (x)/x” noise generated by other on-chip or off-chip digital circuits. As used herein, the term “on-chip” specifies electrical and/or electronic circuits, elements, or components integrally formed on the same integrated circuit structure as the baseband processor 102. Also, as used herein the term “off-chip” specifies that the referenced electrical and/or electronic circuits, elements, or components are not integrally formed on the same integrated circuit as the baseband processor 102. Due to the digital nature of the baseband processor 102 architecture, the filter 136 may comprise multiple n filter modules 136-1-n arranged in parallel to filter the n pairs of voltage signals 134-1-n. The multiple filter modules 136-1-n receive multiple n pairs of voltage signals 134-1-n at controlled voltage levels from the respective n analog multiplexers 116-1-n. The filter modules 136-1-n provide n differential input voltage signals 144₁₋ₙ to the driver modules 137-1-n. The differential filtered input signals comprise n-pairs of input voltage signals 144-1-n, 144-2-n, where the differential filtered input signals are defined as 144₁₋ₙ=(144-1-n)−(144-2-n). The input voltage signals 144-1-n, 144-2-n are provided to the respective n differential-to-single ended transconductance pre-driver modules 164-1-n of the driver portion 110.

The filter modules 136-1-n may employ various types of filters. In one embodiment, the filter modules 136-1-n may be low-pass filters having a predetermined cut-off frequency. In one embodiment the filter modules 136-1-n may comprise a differential topology structure, as opposed to a conventional single-ended structure, to provide better noise immunity in a mixed signal environment (e.g., a combination of analog and digital circuits formed on the same integrated circuit). In addition, in one embodiment, the filter modules 136-1-n may be coupled to an on-chip or off-chip trimmable resistor module 221 (FIG. 2A) to fine tune the characteristic function of the particular filter implementation utilized.

In one embodiment, each low-pass filter module 136-1-n may be implemented as a Bessel filter. Those skilled in the art will appreciate that a Bessel filter is a variety of linear filter with maximally flat group delay (linear phase response) and small overshoot. For example, the low-pass filter modules 136-1-n may be implemented as third-order Bessel filters. In one embodiment, the third-order Bessel filter may be implemented using a fully differential active resistor-capacitor (RC) structure with a cut-off frequency of about 2.5 MHz and a G_{DC} (DC gain) of about 1. In one embodiment, the supply voltage for the filter modules 136-1-n may be approximately 3.3V. The embodiments are not limited in this context.

In low power consumption embodiments, the filter modules 136-1-n may employ a Sallen-Key architecture cascaded by a passive RC network. A fully differential Sallen-Key filter structure may comprise a fully differential operational amplifier (op-amp). The Q of the Sallen-Key filter may be approximately 0.691 and the natural frequency may be fₙ=3.63 MHz, with a first order section natural frequency fₙ₁=3.31 MHz. The current consumption for a Sallen-Key filter may be approximately 80 μA/filter. Simulations of one embodiment of a Sallen-Key filter indicate a frequency accuracy within ±25% with automatically trimmed poly resistors. The embodiments are not limited in this context.

In one embodiment, the driver portion 110 may comprise n driver modules 137-1-n comprising pre-drivers and drivers. The driver modules 137-1-n may comprise n drivers 138-1-n to drive the RF-DAC 104. The pre-driver modules may comprise, for example, n differential-to-single ended converter transconductance (Gₘ) modules 164-1-n (pre-driver modules), an offset/trickle control module 140, and a bias control module 142. The pre-driver modules 164-1-n have a transconductance represented by Gₘ. The embodiments are not limited in this context as other topologies, architectures, and structures may be employed.

As previously described, due to the digital nature of the digital amplitude baseband signals 122 comprising n bits, the driver module may comprise n drivers 138-1-n. The drivers 138-1-n take input currents 166-1-n Iₒᵤₜ₋₁₋ₙ from the pre-driver modules 164-1-n and generate single-ended drive current signals 154-1-n to drive up to n input transistors 158-1-n of the RF-DAC 104. The drivers 138-1-n source currents into the bases of transistors 158-1-n of the RF-DAC 104. In one embodiment, the drivers 138-1-n may be implemented as P-channel MOS (PMOS) integrated circuit drivers, for example. In one embodiment, the transistors 158-1-n may be RF Gallium Arsenide (GaAs) HBT transistors. In one embodiment, the input structure of the RF-DAC 104 may comprise a multiple bit DAC, such as, for example, a 7-bit DAC where the most significant 3-bits are thermometer coded. Accordingly, in one embodiment, the single-ended drive current signals 154-1-n may be scaled to match the input structure of the multiple bit DAC of the RF-DAC 104.

As previously discussed, the baseband processor 102 comprises a differential signal processing structure and the RF-DAC 104 comprises a single-ended signal processing structure. Accordingly, to make the single-ended drive current signals 154-1-n compatible with the single-ended topology of the RF-DAC 104, the pre-driver modules 164-1-n convert the input voltage signals 144-1-n received from the filter modules 136-1-n from differential voltages to single-ended drive current signals 154-1-n.

The offset/trickle control module 140 receives the differential bias voltage signals 126 and an offset voltage signal 146 (V_{trickle}), converts them to differential offset voltage signals 157 and provides them to the pre-driver modules 164-1-n. The pre-driver modules 164-1-n converts the differential offset voltage signals 157 to single-ended trickle current I_{trickle} bias signals to fine tune the drivers 138-1-n based on the differential bias voltage signals 126 voltages Vₕᵢ and Vₗₒ. The trickle currents I_{trickle} are additive with the single-ended drive current signals 154-1-n and provide an additional small amount of controllable current to the bases of the RF-DAC 104 input transistors 158-1-n. As previously described, the differential bias voltage signals 126 (Vₕᵢ, Vₗₒ) may be superimposed on the common mode voltage V_{cm}. The offset/trickle control module 140 simultaneously and dynamically biases the pre-driver modules 164-1-n with the differential bias voltage signals 126 Vₕᵢ and Vₗₒ shifting current signal 166-1-n Iₒᵤₜ₋₁₋ₙ by a positive amount equal to the peak negative amount due to input voltage signals (144-1-n), (144-2-n) while (157-1-n)−(157-2-n)=0 or, i.e., are held equal. In addition, signals 166-1-n Iₒᵤₜ₋₁₋ₙ is also a function of the offset voltage signal 146 V_{trickle} adjusting the current 166-1-n by a small amount regardless of whether the input digital amplitude signals 122 are at logic zeros or logic ones.

The bias control module 142 provides a bias control signal 148 (Vₜᵤₙₑ) to drivers 138-1-n. The bias control signal 148 comprises a tuning voltage signal Vₜᵤₙₑ and β compensation signal generated by respective Vₜᵤₙₑ generator and β compensation modules. The bias control module 142 may be adapted such that the bias control signal 148 biases the driver modules 138-1-n to compensate for CMOS process variations and to minimize the effects of process variations and to maintain a well controlled transconductance Gₘ. The bias control signal 148 compensates for CMOS process variations and provides output current adjustments to accommodate both CMOS process temperature variations and power supply variations. These adjustments may be necessary because the driver modules 138-1-n and pre-driver modules 164-1-n operate in an open-loop configuration.

In addition, the driver modules 138-1-n may be biased to accommodate β variations of the RF-DAC 104 transistors 158-1-n by sensing the ratio of the collector-emitter current to the base-emitter current, or current gain (β), of an HBT dummy device 156 (Q_{dummy}). The dummy device 156 (Q_{dummy}) is formed integrally on the same substrate with transistors 158-1-n of the RF-DAC 104. Therefore, the variations in β due to process variables should be similar for the dummy device 156 (Q_{dummy}) and the transistors 158-1-n. The bias control module 142 determines the β of the dummy device 156 and provides a 1/β compensation signal as part of the bias control signal 148 to the driver modules 138-1-n. To determine the β of the dummy transistor 156, the bias control module 142 outputs a current 150 to the base portion of the dummy transistor 156 in the RF-DAC 104. In addition, the module 142 provides a fixed precision current 152 to the collector of the dummy transistor 156. Module 230 will automatically adjust the current 150 by sensing and maintaining the voltage at the collector of the dummy device 156 such that the collector voltage will be high enough to maintain device 156 in its linear operating range. The voltage is approximately at the half point of the supply in this embodiment. When such condition is achieved, through the adjustment of current 150, the resulting current 150 is 1/β of the current 152. The bias control module 142 uses this 1/β information (and process information) to generate the input bias control signal 148 to the driver modules 138-1-n. The resulting single-ended drive current signals 154-1-n are now proportional to the inverse of the β of the output transistors 158-1-n. Therefore, the collector currents of the transistors 158-1-n are independent of their β variations. The embodiments are not limited in this context.

In various embodiments, the reference portion 111 may comprise, for example, a voltage reference 128 (V_{ref}), a current reference 130 (I_{ref}), and a bandgap reference 132. In one embodiment, the bandgap reference 132 provides a precision 1.2V voltage reference. The bandgap reference 132 and/or a precision resistor located external to the baseband processor 102 may be employed to generate the voltage reference 128 and the current reference 130.

In one embodiment, the baseband processor 102 may comprise an internal interface block 112. The interface portion 112 may comprise a serial interface 160 (SI), one or more test input ports 161 a and/or output ports 161b, and a wideband buffer 162. The serial interface 160 provides a communication link from a computer (PC) to the baseband processor 102. In one embodiment, the serial interface 160 may comprise three ports, for example. The three serial interface 160 ports may receive clock, data, and enable signals. Registers located within the baseband processor 102 may be accessed via the serial interface 160 ports to allow various test modes to be programmed.

The wideband buffer 162 may be capable of driving large on board capacitance(s) external to the chip. In addition, the wideband buffer 162 may be adapted to measure alternating current (AC) characteristics of other on-chip electrical/electronic elements, circuits, blocks, and the like, for example. The wideband buffer 162 may include a test output 163 capable of driving capacitive loads external to the baseband processor 102. For example, a printed circuit board (PCB) coupled to the baseband processor 102 presents a much larger capacitance as compared to the internal capacitance of the baseband processor 102. The internal circuits of the baseband processor 102 may be unable to drive these off-chip capacitive loads at a relative high speed. Thus, the wideband output buffer 162 drives these relatively larger external capacitive loads at relatively high speeds. Accordingly, signals internal to the baseband processor 102 may be viewed externally at reasonably high frequencies. In one embodiment, the wideband buffer 162 may comprise a transconductor and may terminate in low impedance outside the baseband processor 102.

Embodiments may utilize testability techniques to facilitate debugging of the baseband processor 120 via the test input/output ports 161a, b. The test input port 161a receives test input signals. The test input signals are routed to multiple test switches (SW-1-6 FIG. 2A) in the various circuits of the baseband processor 102, e.g., the power control portion 106, the filter portion 108, the driver portion 110, the reference block 111, and/or the interface portion 112 of the baseband processor 102 at designated points. The test switches provide access to internal direct current (DC) and AC behavior of the circuits, for example.

In one embodiment, the techniques and circuits described herein may comprise discrete components or may comprise integrated circuits (IC). For example, the baseband processor 102 may be implemented in a CMOS IC and may be adapted to suppress and/or reduce the quantization noise on the amplitude signal 122 that are generated by other circuits formed of the same CMOS IC substrate. In one embodiment, the baseband processor 102 CMOS IC may comprise RF polar transmitter processing circuits, which may generate unwanted quantization noise. In one embodiment, the baseband processor 102 CMOS IC is fabricated using a 0.4 μ/0.18 μ, 3.3V/1.8V, single-poly, six-metal IBM CMOS process, among others. In one embodiment, the active region of the CMOS IC may comprise an approximate area of 1.5 mm² and a total area of 1.6 mm², for example.

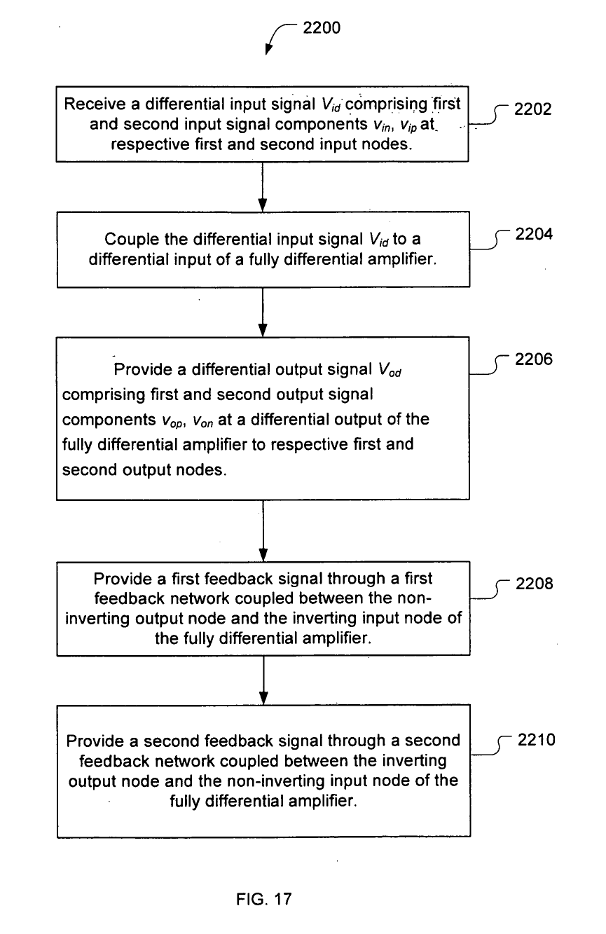

FIG. 2A illustrates one embodiment of a baseband signal processor system 200. The system 200 is one embodiment of the system 100 previously discussed with reference to FIG. 1. In one embodiment, the system 200 may comprise an analog baseband processor module 202 (baseband processor) coupled to an external (off-chip) RF PA 204 (RF-DAC), as shown in FIG. 2B. The baseband processor 202 is one embodiment, of the baseband processor 102 previously discussed with reference to FIG. 1. The baseband processor 202 receives input signals from a baseband integrated circuit module 210 (baseband module). The baseband processor 202 minimizes or reduces quantization noise inherent in digital RF power amplifiers previously described with reference to FIG. 1 and drives the RF-DAC 204. In addition, the baseband processor 202 minimizes or reduces sin (x)/x type of noise inherent in sample-and-hold signals such as the digital signal 122 which originates up-stream from a sample-and-hold system (see FIGS. 17A, B).

In one embodiment, the baseband processor 202 may comprise the power control portion 106, the filter portion 108, and the driver portion 110 previously discussed with reference to FIG. 1. The baseband processor 202 receives the digital baseband amplitude signals 122, assigns voltage levels to the amplitude signals 122 according to the power control portion 106, and filters the signals in the filter portion 108. The driver portion 110 initially converts the processed signals from differential voltages to single-ended drive currents and couples the drive currents to the external RF-DAC 204. The baseband processor 202 processes the received single-ended digital amplitude baseband signals 122 as differential signals in a differential structure. Accordingly, the baseband processor 202 converts the digital amplitude baseband signals 122 from single-ended signals to double-ended differential signals.

The timing realignment module 118 receives the single-ended digital baseband amplitude signals 122 from another baseband integrated circuit 210 which may or not may not be on the same die as system 202. The off-chip baseband integrated circuit 210 may be a CORDIC digital signal processor, for example. In one embodiment, a discrete amplitude baseband signal 122 may comprise n-bits representing the digital amplitude of a sampled signal at a particular point in time. Portions of the most significant bits of the baseband amplitude signals 122 may be thermometer coded. For each of the baseband amplitude signals 122 comprising n-bits, the timing realignment module 118 generates n single-ended time realigned digital segment control signals 124-1-n. Accordingly, the digital segment control signals 124-1-n also may comprise up to n bits (D_{n-1:0}). The timing realignment module 118 comprises latches to realign the digital amplitude baseband signals 122 to remove or minimize timing skews that eventually may result in glitches at the output of the RF-DAC 204 and increase the overall noise error margin of the system 200.

In embodiments comprising n bits (D_{n-1:0}), the timing realignment module 118 is coupled to n analog multiplexers 116-1-n. The single-ended digital segment control signals 124-1-n are effectively the select inputs of the analog multiplexers 116-1-n. The analog multiplexers 116-1-n multiplex the bias voltage signals 126-1-n, 126-2-n from the power control module 114 and translate them into n-pairs of voltage signals 134-1-n, 134-2-n at voltage levels controlled by the power control signal 120.

In one embodiment, the digital amplitude baseband signal 122 may comprise eleven bits (11) forming 11 discrete digital signals, where a predetermined number of the most significant bits of equal weighting may be a result of thermometer coding of the most significant binary weighted bits (e.g., the most significant three (3) bits of a 7 bit binary weighted digital signal). Hence, the digital segment control signals 124-1-11 also comprises 11 bits (D10:0).

The power control module 114 comprises a current mirror 212 and a differential amplifier 214 to generate the n-pairs of bias voltage signals 126-1-n, 126-2-n (Vₕᵢ and Vₗₒ) centered around a reference common mode voltage V_{cm}. Both Vₕᵢ and Vₗₒ are a function of the value of the power control signal 120. The analog bias voltage signals 126-1-n, 126-2-n comprise a first bias voltage signal 126-1a (Vₕᵢ) and a second bias voltage signal 126-2a (Vₗₒ). The power control signal 120 controls the respective amplitudes of the first and second bias voltage signals 126-1a (Vₕᵢ), 126-2a (Vₗₒ), which have opposite polarity relative to V_{cm}. The power control signal 120 input is selectable via switch S6 from a first power control feedback signal V_{seg3SW} received from the RF-DAC 204 or a second power control signal V_{seg3DC} generated by off-chip modules. The outputs of the power control module 114 are coupled to the signal inputs of the analog multiplexers 116-1-n.

The analog multiplexers 116-1-n translate the digital voltage segment control signals 124-1-n into n-pairs of analog voltage signals 134-1-n at voltage levels controlled by the power control module 114. The analog multiplexers 116-1-n multiplex the digital voltage segment control signals 124-1-n with the common mode voltage V_{cm} and the bias voltage signals 126-1-n and 126-2-n (e.g., voltages Vₕᵢ and Vₗₒ) as controlled by the power control signal 120.

The n analog multiplexers 116-1-n receive the time aligned digital segment control signals 124-1-n from the timing realignment module 118. The digital segment control signals 124-1-n are provided to the select inputs of the n analog multiplexers 116-1-n at a predetermined bit rate. In one embodiment, for example, bit rate of the digital segment control signals 124-1-n are provided at a rate of approximately 9.8304 Mb/s.

In one embodiment, each of the analog multiplexers 116-1-n may comprise a 1-bit DAC. The select inputs of the n analog multiplexers 116-1-n are coupled to an enable port 216 that is used to receive an enable signal 220. The enable signal 220 selects one or more transmission gates of the analog multiplexers 116-1-n. Each analog multiplexer 116-1-n may comprise, for example, four transmission gates 218-1-4. Two positively (logic one) enabled transmission gates 218-1 and 218-3 and two negatively (logic zero) enabled transmission gates 218-2 and 218-4. The positive transmission gate 218-1 and the negative transmission gate 218-4 receive the first bias voltage signal 126-1-n (Vₕᵢ) at their respective input ports. The negative transmission gate 218-2 and the positive transmission gate 218-3 receive the second bias voltage signal 126-2a (Vₗₒ) at their respective input ports. The transmission gates 218-1-4 are coupled to the common enable port 216 to receive the enable signal 220.

As shown, the digital segment control signals 124-1-n are the enable signals 220 to the analog multiplexers 116-1-n. When the enable signal 220 is a logic one, the positive transmission gates 218-1, 218-3 are turned on and conduct the respective bias voltage signals 126-1-n, 126-2-n to the output of the multiplexer 118-1-n. When the enable signal 220 is a logic zero, the negative transmission gates 218-2, 218-4 are turned on and conduct the respective bias voltage signals 126-2-n and 126-1-n to the output of the multiplexers 116-1-n. Accordingly, as the digital segment control signals 124-1-n are received at the enable port 216, an individual bit of the digital segment control signal 124-1-n enables two of the four transmission gates 218-1-4. A logic one bit in the digital segment control signals 124-1-n at the enable port 216 selects the positive transmission gates 218-1, 218-3 to conduct the bias voltage signals 126-1-n Vₕᵢ and 126-2a Vₗₒ to corresponding voltage signals 134-1-n and 134-2-n at the output of the multiplexers 116-1-n. A logic zero bit in the digital segment control signals 124-1-n at the enable port 216 selects the negative transmission gates 218-2, 218-4 to conduct the first and second bias voltage signals 126-1-n (Vₕᵢ), 126-2-n (Vₗₒ) to corresponding first and second voltage signals 134-1-n, 134-2-n at the output of the multiplexers 116-1-n. At the respective outputs of the multiplexers 116-1-n the first and second voltage signals 134-1-n, 134-2-n are selectable via switch S1 as inputs to the filter portion 108. If filtering is not required or to conduct tests, switch S3 bypasses the filter portion 108 to couple the first and second voltage signals 134-1-n, 134-2-n to the driver portion 110.

In one embodiment, switches S1 couples the first and second voltage signals 134-1-n, 134-2-n to the filter portion 108. In one embodiment, the filter portion 108 may comprise a filter 136 to reduce quantization and sin (x)/x and environmental noise from other digital circuits, for example. Due to the digital nature of the baseband processor 202 architecture to process n bits of the digital amplitude baseband signals 122, the filter 136 may comprise n multiple filter modules 136-1-n, where n corresponds to the number of bits of the digital amplitude baseband signal 122. The n multiple filter modules 136-1-n receive the n multiple voltage signals 134-1-n, 134-2-n from each of the corresponding transmission gates of the analog multiplexers 116-1-n. To receive the voltage signals 134-1-n, 134-2-n, the filter modules 136-1-n comprise a differential input structure. The filter modules 136-1-n provide n input voltage signals 144-1-n, 144-2-n to the driver portion 110. Accordingly, to provide the voltage signals 134-1-n, 134-2-n to the driver portion 110, the filter modules 136-1-n comprise a differential output structure. In one embodiment, the filter 136 is coupled to a trimmable resistor module 221 to receive an input trim signal 222.

The filter 136 may be implemented using various types of filters. The filter 136 may be implemented as an m-order Bessel filter, where m is any positive integer. In one embodiment, the filter 136 may be a third-order Bessel filter (m=3). In one embodiment, the filter 136 may be a fully differential active resistor-capacitor (RC) third-order Bessel filter structure comprising a differential input and a differential output topology. In one embodiment, for example, the filter 136 may be a low-pass filter implemented with a differential topology. In one embodiment, the low-pass filter 136 may be a third order low-pass Bessel filter with a cut-off frequency of about 2.5 MHz and a DC gain G_{DC} of about 1. A Bessel type low-pass filter provides a linear group delay and small overshoot. In a mixed signal environments (e.g., a combination of analog and digital circuits formed on the same integrated circuit), the fully differential filter structure filter 136 provides better noise immunity than a single-ended filter structure. For low power consumption considerations, in one embodiment the filter 136 may comprise a Sallen-Key architecture cascaded by a passive resistor-capacitor (RC) network comprising a fully differential operational amplifier (op-amp) to implement the fully differential filter structure. In one embodiment, the Q of the Sallen-Key filter may be approximately 0.691 and the natural frequency may be approximately fₙ=3.63 MHz for the second order section and approximately fₙ=3.31 MHz for the first order section. In one embodiment, the supply voltage for the filter 136 may be approximately 3.3.V with a current consumption of approximately 80 μA/filter. Simulations indicate that a filter 136 frequency accuracy of approximately ±25% may be achieved using automatically trimmed poly resistors. It will be appreciated that the embodiments are not limited in this context.

In one embodiment, power control for the system 200 may be achieved by adjusting the amplitude of the n-pairs of bias voltage signals 126-1-n and 126-2-n Vₕᵢ and Vₗₒ, respectively, at the input of the filter 136. At maximum power, for example, the amplitude of the digital amplitude baseband signals 122 may be approximately 300 mV, single-ended. In embodiments comprising n digital amplitude bits as discussed above, the power control portion 106 translates the n digital amplitude bits into n-pairs of differential analog voltage signal levels at the output of the multiplexers 116-1-n based on the time aligned digital segment control signals 124-1-n. The power control signal 120 controls the amplitude of the bias voltage signals 126-1-n and 126-2-n Vₕᵢ and Vₗₒ, respectively.

The filter portion 108 is coupled to the driver portion 110. As previously described, due to the digital nature of the digital amplitude baseband signals 122 comprising up to n bits, the driver portion 110 may comprise n driver modules 137-1-n comprising pre-drivers and drivers. The driver modules 137-1-n may comprise n drivers 138-1-n and the pre-driver modules may comprise n differential-to-single ended converter transconductance (Gₘ) modules 164-1-n (pre-driver modules). The input voltage signals 144-1-n, 144-2-n are coupled to the driver modules 137-1-n. The driver modules 137-1-n may be adapted to convert the n-pair of input voltage signals 144-1-n, 144-2-n into n single-ended drive current signals 154-1-n. The driver modules 138-1-n drive the RF-DAC 204 by sourcing the n single-ended drive current signals 154-1-n into the bases of the transistors 158-1-n (Q₁-Qₙ).

In one embodiment, the filter portion 108 may be bypassed by selecting switch S3 and deselecting switches S1 and S2. If the filter portion 108 is bypassed, the n-pair of voltage signals 134-1-n may be coupled directly to the driver portion 110. In various embodiments, test inputs may couple to the filter 136-1-n. Test input Tᵢₙ₋₀ may couple to the filter 136-1-n by selecting switch S2 and deselecting switch S1. Test input Tₒᵤₜ₋₀ may coupe to the driver modules 137-1-n instead of the n-pairs of input voltage signals 144-1-n, 144-2-n by deselecting switches S4 and selecting switch S5.

The n-pairs of input voltage signals 144-1-n, 144-2-n are coupled to the driver modules 137-1-n. The n-pairs of input voltage signals 144-1-n, 144-2-n may be coupled to the driver modules 137-1-n by selecting switches S4 and deselecting switches S5. As previously discussed, the driver modules 137-1-n comprises n pre-driver modules 164-1-n and n drivers 138-1-n. The driver modules 137-1-n convert the n-pairs of input voltage signals 144-1-n, 144-2-n from differential voltages to single-ended drive current signals 154-1-n to drive the RF-DAC 204 transistors 158-1-n. The pre-driver modules 164-1-n sink output current Iₒᵤₜ₋₁₋ₙ from the drivers 138-1-n. The pre-driver modules 164-1-n comprise two pairs of inputs, a first pair of inputs iₚ₁, iₘ₁ and a second pair of inputs iₚ₂, iₘ₂. The n-pairs of input voltage signals 144-1-n, 144-2-n are applied to the first pair of inputs iₚ₁ and iₘ₁ of the pre-driver modules 164-1-n.

In one embodiment, the driver portion 110 may comprise driver modules 137-1-n, where each module includes a pre-driver module 164 and a driver 138. The driver portion 110 also may comprise an offset/trickle control module 140 and/or a bias control module 142. The offset/trickle control module 140 may comprise a differential amplifier 224 and a trickle DAC 226. In one embodiment, the differential amplifier may be a summer amplifier, for example. The trickle DAC 226 generates voltage signals V_{DACp} and V_{DACm}. The trickle DAC 226 provides the V_{DACp} signal to the non-inverting (+) input of the differential amplifier 224 and V_{DACm} to the inverting (−) input of the differential amplifier 224. The differential amplifier 224 also receives the bias voltage signals 126-1-n (Vₕᵢ) at the inverting (−) input of the differential amplifier 224 and the bias voltage signals 126-2-n (Vₗₒ) at the non-inverting (+) input of the differential power amplifier 224. The differential amplifier 224 applies the offset voltage signals 157-1-n, 157-2-n proportional to the DAC 226 voltages V_{DACp}, V_{DACm} and the bias voltage signals 126-1-n, 126-2-n (Vₕᵢ and Vₗₒ) signals to the second pair of inputs iₚ₂ and iₘ₂ inputs of the pre-driver modules 164-1-n. The offset voltage signals 157-1-n, 157-2-n provide a dynamic biasing current and a small amount of controllable trickle current, proportional to the bias voltage signals 126-2-n (Vₗₒ)+V_{DACp} and 126-1-n (Vₕᵢ)+V_{DACm} to the bases of the RF-DAC 204 transistors 158-1-n (Q₁-Qₙ). The offset voltage signals 157-1-n, 157-2-n supply a dynamic biasing voltage and a small voltage to the second pair of inputs iₚ₂, iₘ₂ of the pre-driver modules 164-1-n.

The driver modules 137-1-n are coupled to the bias control module 142. The bias control module 142 provides the bias control signal 148 to the drivers 138-1-n. In one embodiment, the bias control module 142 may comprise a tuning voltage Vₜᵤₙₑ generator module 228 and a β compensation module 230. The β compensation module 230 generates a signal 232 that is proportional to 1/β to the Vₜᵤₙₑ generator module 228. The drivers 138-1-n are biased by the bias control signal 148 such that the single-ended output current signals 154-1-n are compensated for semiconductor process variations as well as β variation. Thus, the collector currents in the transistors 158-1-n are independent of β. In addition, the bias control module 142 may be adapted such that the bias control signal 148 compensates for CMOS process variations, for example. The bias control signal 148 minimizes the effects of CMOS process variations, maintains well controlled transconductance Gₘ in the pre-driver modules 164-1-n to compensate for CMOS process variations and to provide output current adjustments to accommodate both CMOS process temperature variations and power supply variations. These adjustments may be necessary because the driver modules 138-1-n operate in an open-loop configuration.

The driver modules 138-1-n may be biased to accommodate β variations in the RF-DAC 204 transistors 158-1-n (Q₁-Qₙ). Automatic β compensation may be implemented by sensing the β on a dummy device 156 (Q_{dummy}) integrally formed on the same substrate as the RF-DAC 204 and thus is equivalent to the RF-DAC 204 transistors 158-1-n. The single-ended drive current signals 154-1-n are inversely proportional to β to reflect variations in the RF-DAC 204 transistors 158-1-n β. The transistors 158-1-n are automatically compensated for β variations based on the bias control signal 148 and thus the driver modules 138-1-n output the single-ended drive current signals 154-1-n based on the input bias signal 148. The β of the dummy device 156 is measured as previously described with reference to FIG. 1. The embodiments are not limited in this context.

In various embodiments, the power control portion 106 may further comprise a reference block 234. The reference block 234 may comprise, for example, a voltage reference 128 (V_{ref}), a current reference 130 (I_{ref}), and a bandgap reference 132 (BG). In one embodiment, the bandgap reference 132 may provide a precision voltage reference of 1.2V, for example, to the voltage reference 128 V_{ref} block. In one embodiment, both the voltage reference 128 and the current-reference 130 may be generated based on the bandgap reference 132 and/or a precision resistor Rₚ located external to the baseband processor 202. In one embodiment, the voltage reference 128 output, the current reference 130 output, the Vₕᵢ bias voltage signals 126-1-n and the Vₗₒ bias voltage signals 126-2-n, and the common voltage V_{cm} are provided as inputs to a first output multiplexer 236. The first output multiplexer 236 provides output signal 238 to other circuits external to the baseband processor 202 where any of the inputs may be selected.

The bandgap reference 132 also generates reference signal 240 (I_{PTAT}) and applies it to a p-bit DAC 240, where p is any positive integer. In one embodiment, p=10 and thus the DAC 242 is a 10-bit DAC. The DAC 242 outputs voltage V_{DAC} to the power control generator module 244 to generate an exponential power control signal 246 based on Iₑₓₚ, which may be defined as

$${I}_{exp} = K \cdot {I}_{pref} \cdot {ⅇ}^{\frac{{V}_{DAC} R}{{R}_{in} {V}_{T}}} .$$

In one embodiment of Iₑₓₚ, K is a scaling constant, I_{pref} is a bias input current to the power control generator module 244, V_{DAC} is the output voltage of the DAC 242, Rᵢₙ is the input resistance of the module 244, R is a value of an internal scaling resistor of the module 244, and V_{T} is a threshold voltage of an HBT device internal to the module 244. In one embodiment, the power control generator module 244 may be implemented as a HBT device, where Iₑₓₚ is the collector output current of the HBT device. Accordingly, the power control signal 246 is exponentially proportional to the output voltage V_{DAC}. The feedback power control signal 246 may be applied to the power control module 114 via switch S6. If switch S6 is selected, the feedback power control signal 246 is used as the power control signal 120.

In one embodiment, power control for the system 200 may be achieved by adjusting the amplitude of the n-pairs of bias voltage signals 126-1-n and 126-2-n at the input of the filter modules 136-1-n. At maximum power, for example, the amplitude of the digital amplitude baseband signals 122 may be approximately 300 mV, single-ended. In embodiments comprising n digital amplitude bits as previously discussed, the power control portion 106 translates the n digital amplitude bits into n differential analog signal levels at the output of the multiplexer 116-1-n based on the time aligned digital segment control signals 124-1-n.

In one embodiment, the baseband processor 202 provides a dynamic method to bias the RF-DAC 204 for power control using the offset and trickle current I_{trickle} control via the offset/trickle control module 140. Power control may be implemented by varying the magnitude of the output currents 166-1-n (Iₒᵤₜ₋₁₋ₙ) sunk by the pre-driver modules 164-1-n from the driver modules 138-1-n, respectively. The output currents 166-1-n (Iₒᵤₜ₋₁₋ₙₜ) may be directly controlled by the complementary bias voltage signals 126-1-n Vₕᵢ and bias voltage signals 126-2-n Vₗₒ. The signals Vₕᵢ and Vₗₒ represent the amount of differential voltage impressed above and below the common mode voltage V_{cm}. Dynamic biasing for power control provides a first value of output current 166ₘᵢₙ (I_{out min}) when a bit of the digital amplitude baseband signal 122 is a logic zero (any one of the bits D_{n-1:0} of the digital segment control signal 124-1-n). Dynamic biasing for power control provides a second value of output current 166ₘₐₓ (I_{out max}) when a bit of the digital amplitude baseband signal 122 is a logic one (any one of the bits D_{n-1:0} of the digital segment control signal 124-1-n). The second value of output current 166ₘₐₓ (I_{out max}) may be proportional to the bias voltage signals 126-1-n (Vₕᵢ) or the bias voltage signals 126-2-n (Vₗₒ). For a logic zero condition, one example of the first value of the output current 166ₘᵢₙ (I_{out min}) may be given by equation (29) below. For a logic one condition, one example of the second value of the output current 166ₘₐₓ (I_{out max}) may be given by equation (30) below. The embodiments are not limited in this context.

These characteristics may be realized in accordance with various implementations. For example, in one embodiment, a logic one in digital bit of the digital segment control signals 124-1-n (any one among D_{n-1:0}) may be converted to a set of complementary analog voltage levels. The analog voltages Vᵢₚ₁=Vₕᵢ and Vᵢₘ₁=Vₗₒ may be applied to the respective first pair of inputs iₚ₁ and iₘ₁ of the pre-driver modules 164-1-n, for example. The analog voltages Vᵢₚ₂=Vₕᵢ and Vᵢₘ₂=Vₗₒ may be applied to the respective second pair of inputs iₚ₂ and iₘ₂ of the pre-driver modules 164-1-n, for example. This may be implemented via the analog multiplexers 116-1-n, filters 136-1-n, and offset/trickle control module 140 as previously described, for example. Accordingly, the following transfer function can be derived for the pre-driver modules 164-1-n:

$${I}_{out} = x \frac{\frac{{I}_{ref}}{β}}{{V}_{bw} - {V}_{t}} ( 2 {v}_{ip 1} + 2 {v}_{ip 2} ) \qquad ( 1 )$$

Offset or trickle current control may be implemented by applying the sum of
Vᵢₚ₂=Vₕᵢ+V_{DACp} (2)

And note that
Vᵢₚ₂=−Vᵢₘ₂=−(Vₗₒ+V_{DACm}) (3)

to the differential amplifier 224 as shown. In one embodiment, a third differential pair at the pre-driver modules 164-1-n input, for example, may replace the differential amplifier 224. Equations (1)-(3) are further described below.

In one embodiment, the baseband processor 202 may comprise an interface 248. The interface 248 may comprise a serial interface 250 (SI), one or more test input ports 252 and/or one or more output ports 254. The serial interface 250 provides a communication link from a computer (PC) to the baseband processor 202. The serial interface 250 provides access to one or more test buffers 256. The test buffers 256 include a “test” register, a power control (HT_PWRCTL) register, a offset (trickle) voltage “V_{trickle}” register, a “write-only 8-bit register,” among other general-purpose registers suitable for transferring information in-and-out of the baseband processor 202. In one embodiment, the serial interface 250 may comprise three ports, for example. The three ports may receive clock, data, and enable signals suitable for the operation of the baseband processor 202. The serial interface 250 ports provide access to the test buffers 256 to program the baseband processor 202 in various test modes, for example.

Various embodiments of the baseband processor 202 may comprise testability techniques to facilitate debugging via the test input/output ports 252, 254. The interface 248 may further comprise an input de-multiplexer 258 to receive multiple test inputs via the test input ports 252. The test input port 252 receives one or more test input signals Tᵢₙ₋₀ to Tᵢₙ₋ₙ into the input de-multiplexer 258. These test signals Tᵢₙ₋₀ to Tᵢₙ₋ₙ may be applied from the input de-multiplexer 252 to various test points on the baseband processor 202 via the switches S2 and S5. As previously discussed, multiple test switches S1-S5 are located at designated test points in the power control portion 106, the filter portion 108, the driver portion 110, the reference block 234, and/or the interface 248. These test switches S1-S5 provide access to the internal DC and AC behavior of the baseband processor 202, for example.

The interface 248 may further comprise an output multiplexer 260 to receive the test signals Tₒᵤₜ₋₀ to Tₒᵤₜ₋ₙ from the various test points on the baseband processor 202 via switches S2 and S5. The output multiplexer 260 couples to a wideband buffer 262 to drive large off-chip capacitance(s) via the one or more output ports 254. The test output port 254 drives one or more test signals Tₒᵤₜ₋₀-Tₒᵤₜ₋ₙ from the output test multiplexer 260 via the wideband buffer 262. The test signals Tₒᵤₜ₋₀-Tₒᵤₜ₋ₙ are received by the output multiplexer 260 from any of the test switches S1-S5, for example. In addition, the wideband buffer 262 may be adapted to measure alternating current (AC) characteristics of other on-chip electrical/electronic elements, circuits, blocks, and the like, for example. In one embodiment, the wideband buffer 262 may be a transconductor with outputs terminated in low impedance external to the baseband processor 202.

The dynamic biasing and offset control of the RF-DAC 204 for power control with offset (trickle) control using the baseband processor 202 are further described herein below.

In one embodiment, for example, the bit rate of the digital segment control signals 124-1-n may be approximately 9.8304 Mb/s. The digital segment control signals 124-1-11 may comprise comprises 11 bits (D10:0). The unregulated supply voltage V_{dd} may vary from approximately 2.0 to 4.6V. The common mode voltage V_{cm} is approximately 2.0V. The bias voltage signals 126-1-n range from 0 to +300 mV relative to the V_{cm} of 2.0V. The bias voltage signals 126-2-n range from 0 to −300 mV relative to the V_{cm} of 2.0V. The bias voltage signals 126-1-n, 126-2-n are controlled by the power control signal 120. The range of the bias voltage signals 126-1-n, 126-2-n is approximately ±300 mV with a variation of ±3 mV, for example. Thus, the maximum swing for the voltage signals 134-1-n, 134-2-n into the filter modules 136-1-n at voltage levels relative to the V_{cm} are approximately 2.0V±0.3V. Taking into account the variation in the bias voltage signals 126-1-n, 126-2-n, the maximum swing for the voltage signals 134-1-n, 134-2-n is approximately 2.0V±0.303V. For a β≈56, the single-ended drive current signals 154-1-n (I_{b1-n}) will vary. At the n=0, I_{b0}≈1.25 μA to 0.3125 mA and at n=11, I_{b11}≈20 μA to 5 mA. If I_{trickle} varies from

$$\frac{{I}_{b}}{250} -> \frac{{I}_{b}}{30} ,$$

then for I_{b11}≈20 μA, the trickle current will vary I_{b11-trickle}≈80 nA to 0.6 μA, and for I_{b11}≈5 mA, the trickle current will vary I_{b11-trickle}≈20 μA to 167 μA. The embodiments are not limited in this context.

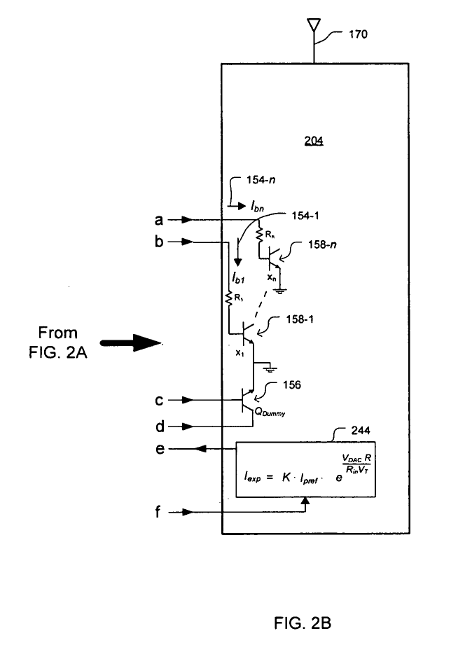

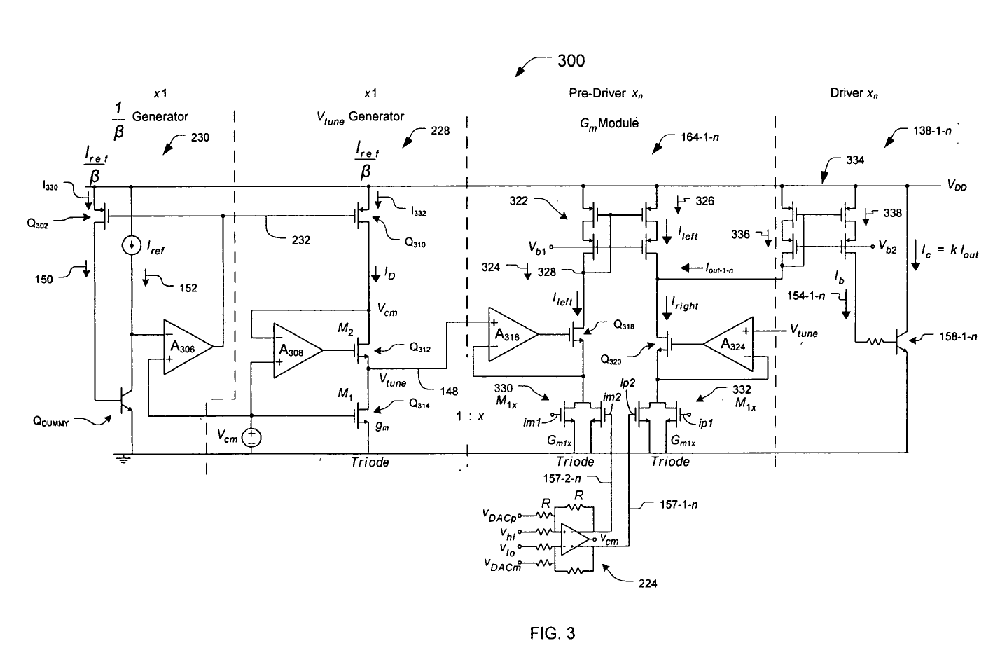

FIG. 3 illustrates one embodiment of a driver portion 300 of the systems 100, 200 discussed above with reference to FIGS. 1 and 2. The driver portion 300 is one embodiment of the driver portion 110 discussed above with reference to FIGS. 1 and 2. Accordingly, the driver portion 300 comprises the β compensation module 230, the Vₜᵤₙₑ generator module 228, the pre-driver modules 164-1-n, and the drivers 138-1-n. A common supply voltage V_{dd} is applied to these modules.

In one embodiment, the β compensation module 230 comprises a transistor Q₃₀₂ coupled to a transistor Q_{Dummy}. The transistor Q_{Dummy} is coupled to an amplifier A₃₀₆ and is coupled to the current reference 152 (I_{ref}). In one embodiment, the transistor Q₃₀₂ is a P-MOSFET and the transistor Q_{Dummy} is a GaAs HBT, although the embodiments are not limited in this context. The transistor Q₃₀₂ drives a current 150 into the base of the transistor Q_{Dummy}. The current reference 152 forces the collector of the transistor Q_{Dummy} to drive I_{ref}. Accordingly, the current 150 into the base of the transistor Q_{Dummy} is approximately

$$\frac{{I}_{ref}}{β} .$$

The common mode voltage V_{cm} is coupled to the non-inverting (+) input of the amplifier A₃₀₆. Because little or no current flows into the inverting (−) and non-inverting (+) inputs of the amplifier A₃₀₆, the input voltages at the inverting (−) and non-inverting (+) inputs are substantially equal and thus the voltage at the inverting (−) input of the amplifier A₃₀₆ (and the collector of the transistor Q_{Dummy}) is V_{cm}. The output of the amplifier A₃₀₆ is the signal 232 that drives the gates of Q₃₀₂ and Q₃₁₀ whose drain currents are proportional to 1/β and is applied to the Vₜᵤₙₑ generator module 228.

The Vₜᵤₙₑ generator module 228 comprises a transistor Q₃₁₀ that is similar to and closely matches the transistor Q₃₀₂. Accordingly, in one embodiment, the transistor Q₃₀₂ also is a P-MOSFET transistor. The drain of the transistor Q₃₁₂ is coupled to the drain of a transistor Q₃₁₄. The source of the transistor Q₃₁₂ is coupled to the drain of a transistor Q₃₁₄ at a node. The bias control signal 148 (Vₜᵤₙₑ) is developed at this node. In one embodiment, the transistors Q₃₁₂, Q₃₁₄ are N-MOSFET transistors biased in triode mode, for example. The transistors Q₃₁₂, Q₃₁₄ may be characterized by a transconductance represented by gₘ. The Vₜᵤₙₑ generator module 228 also comprises an amplifier A₃₀₈. The output of the amplifier A₃₀₈ is coupled to the gate of the transistor Q₃₁₂ and the inverting (−) input of the amplifier A₃₀₈ is coupled to the drain of the transistor Q₃₁₂. The common mode voltage V_{cm} is coupled to the non-inverting (+) input of the amplifier A₃₀₈ and is coupled to the gate of the transistor Q₃₁₄. Accordingly, the voltage at the inverting (−) input of the amplifier A₃₀₈ and the drain of the transistor Q₃₁₂ also is V_{cm}. The output of the amplifier A₃₀₆ is coupled to the gates of the transistors Q₃₀₂, Q₃₁₀. Accordingly, the drain current I_{D}, which is proportional to 1/β, driven by the transistor Q₃₁₀ is equal to the drain current in the transistor Q₃₁₂. The drain current I_{D} is forced into the transistor Q₃₁₄ to generate the bias control signal 148 (Vₜᵤₙₑ) while keeping the transistor Q₃₁₄ in triode mode. The sources of the transistors Q₃₀₂, Q₃₁₀ are coupled to the common supply voltage V_{dd} and the gates of these transistors Q₃₀₂, Q₃₁₀ are coupled to the output of the amplifier A₃₀₆. Accordingly, the current driven by the transistor, I_{D}, is equal to

$$\frac{{I}_{ref}}{β} .$$

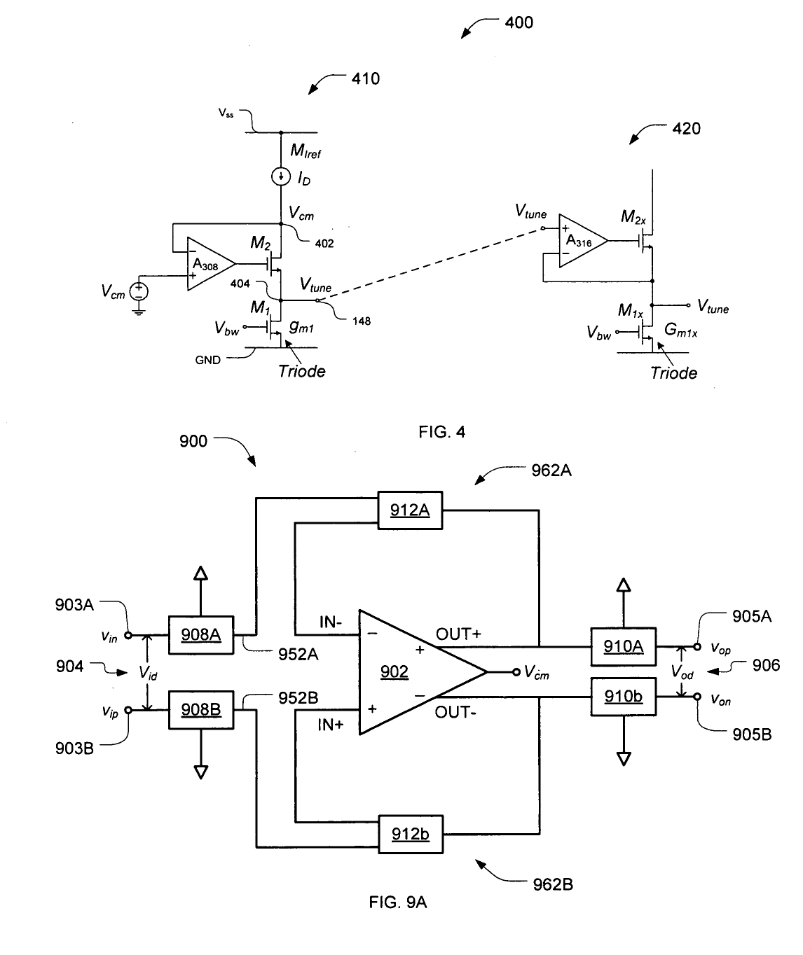

The Vₜᵤₙₑ generator module 228 is described further below with reference to FIG. 4.

The driver modules 137-1-n comprise the pre-driver modules 164-1-n, which comprises an amplifier A₃₁₆ to receive the bias control signal 148 Vₜᵤₙₑ at a non-inverting (+) input. The pre-driver modules 164-1-n also comprise an amplifier A₃₂₄ to receive the bias control signal 148 Vₜᵤₙₑ at a non-inverting (+) input. The amplifiers A₃₁₆ and A₃₂₄ are connected as buffers with their outputs coupled to respective current regulator transistors Q₃₁₈ and Q₃₂₀. The drains of the current regulator transistors Q₃₁₈ and Q₃₂₀ are coupled to a current mirror 322. The current mirror has a first current path 324. The current I_{left} driven in the first current path 324 is copied in the second current path 326. Thus I_{left} is sourced into the drain of Q₃₂₀. The current regulator transistor Q₃₂₀ sinks current I_{right} due to transistor 332. The output current 166-1-n Iₒᵤₜ₋₁₋ₙ is the difference between I_{right} and I_{left} i.e. Iₒᵤₜ₋₁₋ₙ=I_{right}−I_{left}. The I_{left} current is sunk into the common drains of a first differential triode input cell Q₃₃₀ comprising transistors M₁ₓ and the I_{right} current is sunk into the common drains of a second differential triode input cell Q₃₃₂ comprising transistors M₁ₓ.

The transistors M₁ₓ forming the first and second differential triode input cells Q₃₃₀ and Q₃₃₂ may be characterized by a transconductance represented by Gₘ₁ₓ. The first and second pairs of inputs to the pre-driver modules 164-1-n, e.g., the first pair of inputs iₚ₁, iₘ₁ and the second pair of inputs iₚ₂, iₘ₂, correspond to the gates of the first and second differential triode input cells Q₃₃₀, Q₃₃₂ as follows. The second differential triode input cell Q₃₃₂ comprises the first input iₚ₁ of the first pair and the first input iₚ₂ of the second pair. The first differential triode input cell Q₃₃₀ comprises the second input iₘ₁ of the first pair and the second input iₘ₂ of the second pair. As previously discussed, the iₘ₁ and the iₚ₁ inputs receive respective the n-pairs of input voltage signals 144-1-n, 144-2-n. Also, as previously discussed, the iₘ₂ and the iₚ₂ inputs receive the offset voltage signals 157-1-n, 157-2-n proportional to V_{DACp}, V_{DACm}, and bias voltage signals 126-1-n, 126-2-n (Vₕᵢ and Vₗₒ) from the differential amplifier 224.

The driver modules 137-1-n also comprise the drivers 138-1-n. The drivers 138-1-n comprise a current mirror 334. The current mirror 334 comprises a first current path 336 and a second current path 338. Due to the structure of the current mirror 334, the current Iₒᵤₜ₋₁₋ₙ in the first current path 336 is copied in the second current path 338 and scaled by the ratio (k) of the mirroring device. Therefore, the current in the second current path 338 is k·Iₒᵤₜ₋₁₋ₙ. The current k·Iₒᵤₜ₋₁₋ₙ drives the base of the transistor 158-1-n in the RF-DAC 204 (shown in FIGS. 1, 2 and 3). The current Iₒᵤₜ₋₁₋ₙ is proportional to the current I_{left}, which is proportional to Vₜᵤₙₑ. The voltage Vₜᵤₙₑ is proportional to the current

$$\frac{{I}_{ref}}{β} .$$

Therefore, the collector current IC of the transistor 158-1-n is independent of the transistor β.

In one embodiment, V_{dd}≈2.85V, I_{ref}≈20 μA, and the β varies from 40 to 140. The transistor Q_{DUMMYηβ}≈52 and σ_{β}≈15%. The saturation voltage for the transistor Q₃₁₄≈1.11V. The gₘ for the transistor Q₃₁₄ at β≈56 is ≈9 μS. At β≈42, the bias control signal 148 Vₜᵤₙₑ≈217 mV, and at β≈62, the bias control signal 148 Vₜᵤₙₑ≈28 mV. The embodiments are not limited in this context.

FIG. 4 illustrates one embodiment of a system 400 illustrating process variation and Gₘ control. The system 400 comprises a “master” tuning voltage Vₜᵤₙₑ generator module 410 (master module) coupled to a “slave” pre-driver module 420 (slave module). The bias control signal 148 (Vₜᵤₙₑ) at node 404 generated by the master module 410 is coupled to the slave module 420. The master module 410 is equivalent to components in the Vₜᵤₙₑ generator module 228 and the slave module 420 is equivalent to components in the pre-driver modules 164-1-n previously described with reference to FIG. 3. The master module 410 is coupled to a supply voltage V_{dd}. The master module 410 comprises a constant current source M_{Iref}, an amplifier A₃₀₈, a first transistor M₁, and a second transistor M₂. The first transistor M₁ is biased to operate in triode mode. The first transistor M₁ has a transconductance gₘ₁. A common mode voltage V_{cm} is coupled to the non-inverting (+) input of the amplifier A₃₀₈. The inverting (−) input of the amplifier A₃₀₈ is coupled to the drain of the second transistor M₂, thus forcing the common mode voltage V_{cm} at the drain node 402 of the second transistor M₂. The output of the amplifier A₃₀₈ is coupled to the gate of the second transistor M₂. The source of the second transistor M₂ is coupled to the drain of the first transistor M₁ forming an output node 404. The bias control signal 148 Vₜᵤₙₑ is generated at the output node 404. The source of the first transistor M1 is coupled to signal return or ground 406. A voltage V_{bw} is coupled to the gate of the first transistor M₁. The constant current source M_{Iref} drives current I_{D} through the first and second transistors M₁, M₂.

The master module 410 forces the current I_{D} into the first transistor M₁ to generate the bias control signal 148 Vₜᵤₙₑ while the first transistor M₁ is in triode mode. The transconductance of the first transistor gₘ₁ may be determined by equation (4):

$${g}_{m 1} = \frac{{I}_{D}}{{V}_{bw} - {V}_{t}} \\ for \\ {V}_{tune} < {V}_{bw} - {V}_{t} \qquad ( 4 )$$

Equation (4) says that given I_{D} and V_{bw} gₘ₁ is determined. But it does not provide the value of the bias control signal 148 Vₜᵤₙₑ. However, according to the triode transconductance equation (5) relates gₘ₁ to Vₜᵤₙₑ as follows:
gₘ₁=β·Vₜᵤₙₑ (5)

Substituting equation (4) into equation (5) to eliminate gₘ₁ provides an expression for the bias control signal 148 Vₜᵤₙₑ in equation (6) in terms of the independent variables, which may be controller by the circuit designer.

$${V}_{tune} = \frac{{g}_{m}}{β} = \frac{{I}_{D}}{( μ {C}_{ox} \frac{W}{L} ) ( {V}_{bw} - {V}_{t} )} \qquad ( 6 )$$

where β is defined as:

$$β = μ {C}_{ox} \frac{W}{L} \qquad ( 7 )$$

Where μ is the [[electron]] mobility, Cₒₓ is the capacitance density of the oxide layer, W is the width the channel, and L is the length of the channel of the first transistor M₁.

Equation (6) is the master module 410 bias control signal 148 tuning voltage Vₜᵤₙₑ “generator” equation. From equation (6), to keep the first transistor M₁ well inside the triode region, the bias control signal 148 Vₜᵤₙₑ should be small. This may be achieved by making I_{D} and L small and W large. In addition, a large V_{bw} should be used based on equation (8):
Vₛₐₜ=V_{bw}−V₁>>Vₜᵤₙₑ (8)

Accordingly, Vₛₐₜ is completely determined by V_{bw} and is independent of I_{D}, W, and L.

With reference now back to FIGS. 2 and 3, and still in FIG. 4, the pre-driver modules 164-1-n on the slave module 420 side comprises transistors M₁ₓ and M₂ₓ with a respective transconductances of Gₘ₁ₓ, Gₘ₂ₓ the tuning voltage 148 Vₜᵤₙₑ is an independent variable.
i_{b}=Gₘ₁ₓvᵢₙ (9)
where Gₘ₁ₓ is under the control of the tuning voltage 148 Vₜᵤₙₑ, therefore the appropriate equation is equation (10):

$$\begin{matrix}gm = \frac{\partial {I}_{D}}{\partial {V}_{GS}} = μ {C}_{ox} \frac{W}{L} {V}_{DS} = β {V}_{DS} and \\ & ( 10 ) \\ {G}_{m 1 x} = μ {C}_{ox} \frac{W \cdot x}{L} {V}_{tune} & ( 11 )\end{matrix}$$

where x denotes a scaling factor. To show that Gₘ₁ₓ is less dependent on process variation, equation (6) is substituted into equation (11) to arrive at equation (12):

$${G}_{m 1 x} = μ {C}_{ox} \frac{W \cdot x}{L} \frac{{I}_{D}}{( μ {C}_{ox} \frac{W}{L} ) ( {V}_{bw} - {V}_{t} )} = \frac{x \frac{{I}_{ref}}{β}}{{V}_{bw} - {V}_{t}} \qquad ( 12 )$$

which leads to equation (13):

$${G}_{m 1 x} = \frac{x \frac{{I}_{ref}}{β}}{{V}_{bw} - {V}_{t}} \qquad ( 13 )$$

One observation about equations (4) and (13) is that the Gₘs are not completely independent of process variation. The Gₘs will remain a function of the threshold voltage Vₜ because the term Vₜ is in the denominator. For slow processes where the Vₜ is bigger, the Gₘ is larger. However, process variations involving μ and Cₒₓ are removed. Thus Gₘ suffers less process variations.

The independence of the common mode voltage V_{cm} is now described with reference back to FIG. 3. Accordingly, the output current Iₒᵤₜ₋₁₋ₙ from the pre-driver modules 164-1-n is the difference of the two branches:
Iₒᵤₜ₁₋ₙ=I_{right-1-n}−I_{left-1-n} (14)
Iₒᵤₜ₋₁₋ₙ=Gₘ₁ₓ[(Vᵢₚ₁+Vᵢₚ₂)−(Vᵢₘ₁+Vᵢₘ₂)] (15)

where each input signal is consisted of DC bias and small signal components:
Vᵢₚ₁=V_{cm}+vᵢₚ₁ (16)
Vᵢₚ₂=V_{cm}+vᵢₚ₂ (17)
Vᵢₘ₁=V_{cm}+vᵢₘ₁ (18)
Vᵢₘ₂=V_{cm}+vᵢₘ₂ (19)

Substituting the above into equation (15), shows that Iₒᵤₜ₋₁₋ₙ is independent of V_{cm}:
Iₒᵤₜ₋₁₋ₙ=Gₘ₁ₓ[(V_{cm}+vᵢₚ₁+V_{cm}+vᵢₚ₂)−(V_{cm}+vᵢₘ₁+V_{cm}+vᵢₘ₂)] (20)
Iₒᵤₜ₋₁₋ₙ=Gₘ₁ₓ[(vᵢₚ₁+vᵢₚ₂)−(vᵢₘ₁+vᵢₘ₂)] (21)

With reference now to FIGS. 1, 2, and 3, in one embodiment, dynamic biasing and power control may be implemented by biasing the pre-driver modules 164-1-n such that when vᵢₚ₁ and vᵢₘ₁ correspond to a logic zero, then Iₒᵤₜ₋₁₋ₙ=0. Meanwhile when vᵢₚ₁ and vᵢₘ₁ correspond to a logic one, then Iₒᵤₜ₋₁₋ₙ=Iₒᵤₜ₋₁₋ₙ(vₕᵢ, vₗₒ) where vₕᵢ and vₗₒ are controlled by the power control signal 120 which is dynamic. This may be achieved by setting vᵢₚ₂=vₕᵢ and vᵢₘ₂=vₗₒ. Accordingly, with this setting, equation (21) becomes:
Iₒᵤₜ₋₁₋ₙ=Gₘ₁ₓ[(vᵢₚ₁+vₕᵢ)−(vᵢₘ₁+vₗₒ)] (22)

where vᵢₚ₁ is an array of n signals and vᵢₘ₁ is an array of n signals because of the analog multiplexer 116-1-n (FIGS. 1 and 2). The swing of the amplitude modulated signal vᵢₚ₁ and vᵢₘ₁ is between vₗₒ and vₕᵢ.

For a logic one condition vᵢₚ₁=vₕᵢ and vᵢₘ₁=vₗₒ. Accordingly, equation (22) becomes:
Iₒᵤₜ₋ᵢ₋ₙ=Gₘ₁ₓ4vᵢₚ₁ (23)

where these relationships are used vᵢₘ₁=−vᵢₚ₁ and vₗₒ=−vₕᵢ because both sets are complementary signals.

For a logic zero condition vip1=vlo and vim1=vhi. Accordingly, equation (22) becomes:
Iₒᵤₜ₋₁₋ₙ=Gₘ₁ₓ[(vₗₒ+vₕᵢ)−(vₕᵢ+vₗₒ)]=0 (24)

Due to component mismatches and other imprecision, Iₒᵤₜ₋₁₋ₙ may not be exactly zero. In addition, the RF-DAC 104 (204) may require a small amount of current even when a logic zero is present. This feature may be implemented by making vᵢₚ₂ equal to the sum of both vₕᵢ and V_{DACp}. Mathematically this becomes:
vᵢₚ₂=vₕᵢ+v_{DACp} (25)

and
vᵢₘ₂=vₗₒ+v_{DACm} (26)

With these two expressions, equation (21) becomes:
Iₒᵤₜ₋₁₋ₙ=Gₘ₁ₓ[(vᵢₚ₁+vₕᵢ+v_{DACp})−(vᵢₘ₁+vₗₒ+v_{DACm})] (27)

With the complementary properties of the small signals and substituting Gₘ₁ₓ from equation (13) into equation (26) to eliminate Gₘ₁ₓ we arrive at the following transfer function for the driver modules 137:

$${I}_{out - 1 - n} = \frac{\frac{{xI}_{ref}}{β}}{{V}_{bw} - {V}_{t}} ( 2 {v}_{ip 1} + 2 {v}_{hi} + 2 {v}_{DACp} ) \qquad ( 28 )$$

When the input logic is zero, vᵢₚ₁=vₗₒ=−vₕᵢ, equation (27) becomes:

$${I}_{out - 1 - n} = \frac{\frac{{xI}_{ref}}{β}}{{V}_{bw} - {V}_{t}} ( 2 {v}_{DACp} ) \qquad ( 29 )$$

which comprises only the DAC offset (trickle) voltage component v_{DACp} regardless of what the power control signal 120 level setting is.

When the input logic is one, vᵢₚ₁=vₕᵢ and Iₒᵤₜ₋₁₋ₙ is:

$${I}_{out - 1 - n} = \frac{\frac{{xI}_{ref}}{β}}{{V}_{bw} - {V}_{t}} ( 4 {v}_{hi} + 2 {v}_{DACp} ) \qquad ( 30 )$$

which is a function of the power control signal 120.

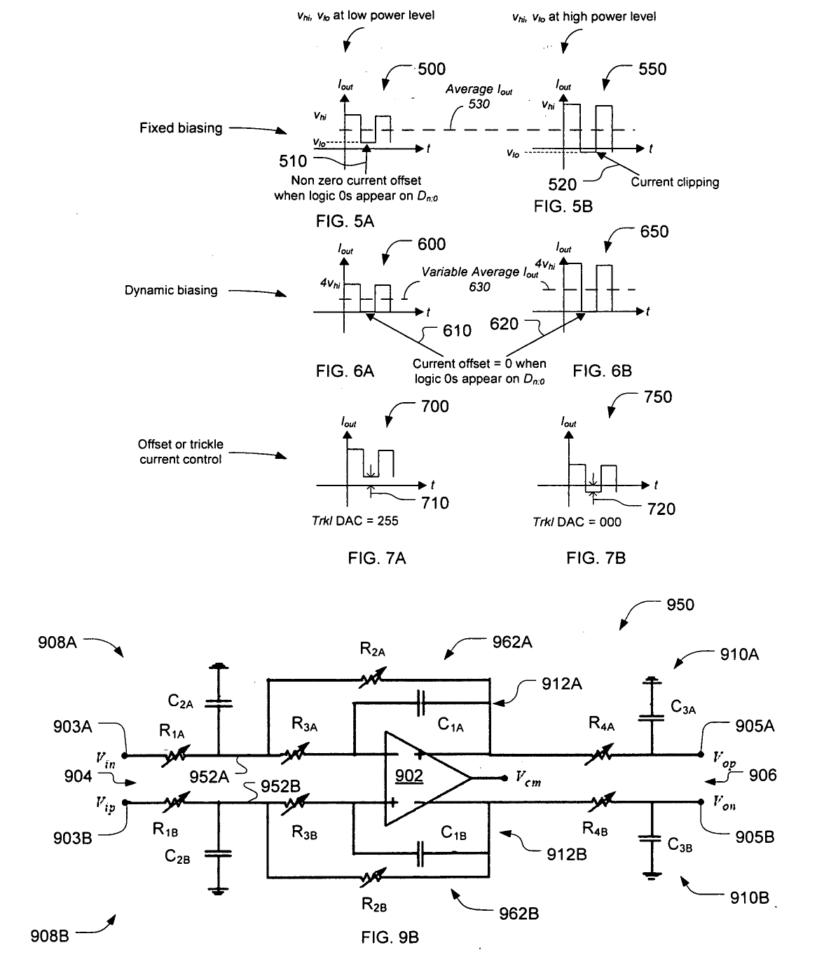

FIGS. 5A, 6A, and 7A illustrate embodiments of biasing timing diagrams 500, 600, 700 respectively, for power control when vₕᵢ and vₗₒ are controlled at a low power level by the input power control signal 120. FIGS. 5B, 6B, and 7B illustrate embodiments of biasing timing diagrams 550, 650, 750, respectively, for power control when vₕᵢ and vₗₒ are controlled at a high power level by the input power control signal 120. In the timing diagrams 500, 550, 600, 650, 700, 750, Iₒᵤₜ₋₁₋ₙ is shown along the vertical axis and time (t) is shown along the horizontal axis.

FIGS. 5A and 5B illustrate embodiments of dynamic biasing diagrams for power control and minimal control in fixed biasing implementations. Dynamic biasing diagrams 500 and 550, respectively, illustrate embodiments of dynamic biasing diagrams for power control and minimal control in fixed biasing implementations. FIG. 5A shows that in a fixed biasing implementation at low power levels, Iₒᵤₜ₋₁₋ₙ has a non-zero offset current 510 when logic zeroes appear on D_{n-1:0}. Under high power levels, FIG. 5B shows that Iₒᵤₜ₋₁₋ₙ current is clipped 520. The dashed line shows a fixed average Iₒᵤₜ₋₁₋ₙ 530.

FIGS. 6A and 6B illustrate embodiments of dynamic biasing diagrams for power control and minimal current control for dynamic biasing implementations. Timing diagrams 600 and 650, respectively, illustrate embodiments of dynamic biasing diagrams for power control and minimal current control for dynamic biasing implementations. FIGS. 6A, 6B show that in a dynamic biasing implementation at both low and high power levels, Iₒᵤₜ₋₁₋ₙ has a zero offset current 610, 620 when logic zeroes appear on D_{n-1:0}. The dashed line shows a dynamic or variable average Iₒᵤₜ₋₁₋ₙ 630.

FIGS. 7A and 7B illustrate embodiments of dynamic biasing diagrams for power control and minimal current control for offset or trickle control biasing implementations. Timing diagrams 700 and 750, respectively, illustrate embodiments of dynamic biasing diagrams for power control and minimal current control for offset or trickle control biasing implementations. In the illustrated timing diagrams 700, 750 the trickle-DAC 226 is an 8-bit DAC with digital inputs ranging from 000 to 255. Accordingly, FIG. 7A illustrates a positive offset current 710 effect on the Iₒᵤₜ₋₁₋ₙ current when the trickle-DAC 226 input is 255. FIG. 7B illustrates a negative offset current 720 effect on Iₒᵤₜ₋₁₋ₙ when the trickle-DAC input is 000.

FIG. 8A is a diagram illustrating one embodiment of a post RF-DAC 204 band pass filter 800 implementation. The RF-DAC 204 comprises a series of inputs 802-1-n to receive a series of input signals 804-1-n. In one embodiment, the inputs 802-1-n may be coupled to the transistors 158-1-n (Q₁-Qₙ) previously described. The input signals 804-1-n may represent any of the signals previously described generated or occurring prior to the RF-DAC 204 stage inputs 802-1-n. In one embodiment, the input signals 804-1-n may represent the n pairs of voltage signals 134-1-n at controlled voltage levels. The RF-DAC 204 comprises an RF input 810 to receive RF signals. The output signals 820-1-n of the RF-DAC 204 are coupled to the antenna 170. The output signals 820-1-n in a first receive frequency band (e.g., cell band 824-849 MHz) may be post filtered (after the RF-DAC 204) via a first band pass filter 830 at the receiver side. The output signals 820′-1-n in a second receive frequency band (e.g., PCS band 1850-1910 MHz) may be post filtered (after the RF-DAC 204) via a second band pass filter 832.

FIG. 8B is a diagram illustrating one embodiment a pre RF-DAC 204 low pass filter 850 implementation. The series of input signals 804-1-n are now low pass filtered by n low pass filters 860-1-n. The filtered output signals 870-1-n of the RF-DAC 204 are coupled to the antenna 170. The filtered output signals 870-1-n in a first receive frequency band (e.g., cell band 824-849 MHz) and the filtered output signals 820′-1-n in a second receive frequency band (e.g., PCS band 1850-1910 MHz) do not require post filtering provided that the RF-DAC 204 is substantially linear.

In one embodiment, the baseband processor 202 removes the quantization noise that is inherently generated by digital-to-analog converters prior to the RF-DAC 204 or antenna 170 by pre-filtering the drive signals 804-1-n in n low pass filters 860-1-n. Accordingly, in one embodiment, the baseband processor 202 eliminates the necessity to filter the noise at the antenna 170 with expensive, large, and power inefficient components, for example. Experimentally measured data illustrated and discussed herein below indicate favorable noise suppression results at the receive band. In one embodiment, AM/AM correction may further improve performance, for example. The embodiments are not limited in this context.

FIG. 9A illustrates one embodiment of a fully differential analog filter 900 (differential filter 900). The fully differential filter 900 comprises a differential input 904 to receive a differential input signal V_{id}. The differential input 904 comprises a first input node 903A and a second input node 903B to receive respective input signal components vᵢₙ, vᵢₚ (e.g., voltage signals 134-1-n, 134-2-n, respectively). The fully differential filter 900 comprises a differential output 906 to provide a filtered differential signal V_{od}. The differential output 906 comprises a first output node 905A and a second output node 905B to provide respective output signal components vₒₚ, vₒₙ (e.g., input voltage signals 144-1-n, 144-2-n, respectively). The fully differential filter 900 comprises a fully differential amplifier 902. The fully differential amplifier 902 comprises a non-inverting input node IN+ and an inverting input node IN− coupled to the differential input 904. The fully differential amplifier 902 comprises a non-inverting output node OUT+ and an inverting output node OUT− coupled to the differential output 906. A first feedback network 912A located in feedback loop 962A is coupled between the non-inverting output node OUT+ and the inverting input node IN− of the fully differential amplifier 902. A second feedback network 912B located in feedback loop 962B is coupled between the inverting output node OUT− and the non-inverting input node IN+ of the fully differential amplifier 902.

A first input network 908A is coupled between the first input node 903A and the first feedback network 912A. A first output network 910A is coupled between the non-inverting output node OUT+ and the first output node 905A. A second input network 908B is coupled between the second input node 903B and the second feedback network 912B. A second output network 910B is coupled between the inverting output node OUT− and the second output node 905B. In one embodiment, the first input network 908A, the first output network 910A, and the first feedback network 912A are electrically symmetric with the respective second input network 908B, the second output network 910B, and the second feedback network 912B.

In one embodiment, the electrically symmetric first and second input networks 908A, B, the first and second output networks 910A, B, and the first and second feedback networks 912A, B define a differential active resistor-capacitor (RC) third-order Bessel filter.

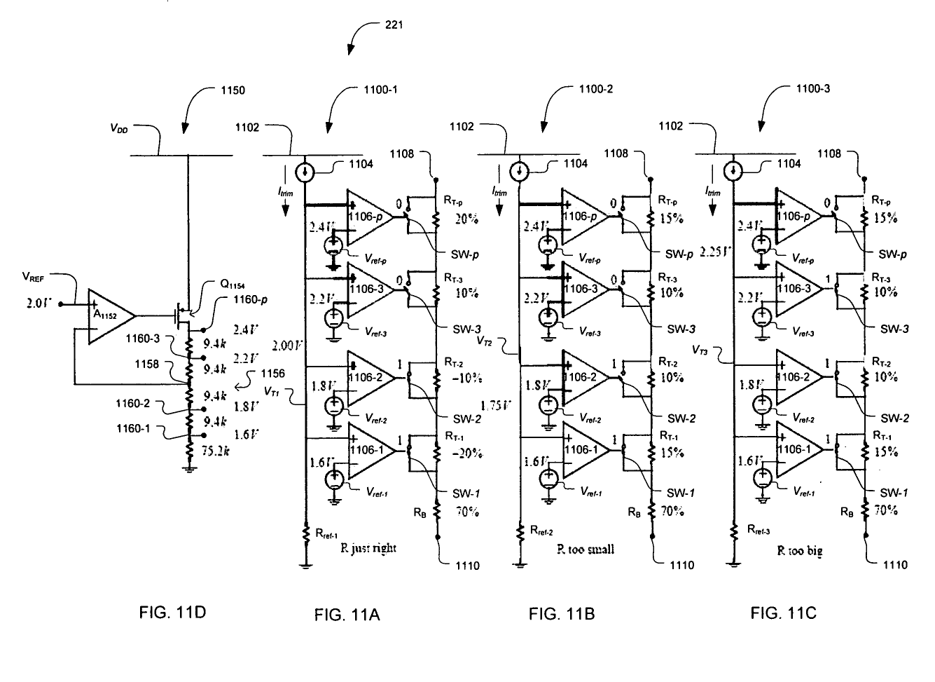

In one embodiment, a trimmable resistor module 221 in FIG. 2A may be coupled to the fully differential amplifier 902. In one embodiment, the trimmable resistor module 221 may comprise a resistor, a logic controlled switch coupled in parallel with the resistor, and a comparator coupled to the logic controlled switch. The output of the comparator controls whether the logic controlled switch is in a conducting or non-conducting state. The first input node is coupled to the comparator to receive a reference voltage and a second input node is coupled to the comparator to receive a threshold voltage. The comparator is to activate the logic controlled switch when the threshold voltage exceeds the reference voltage. A reference resistor is coupled to the second input node and a current source is coupled to the second input node to drive a reference current through the reference resistor to generate the threshold voltage. The trimmable resistor module 221 is described in additional detail below with respect to FIGS. 11A, B, C, D.

FIG. 9B illustrates one embodiment of an analog differential filter 950 (differential filter 950) comprising the fully differential topology of the differential filter 900 shown in FIG. 9A. The fully differential topology of the differential filter 950 comprises the differential input 904 as well as the differential output 906. In one embodiment, the filter modules 136-1-n of the baseband processor 202 may be implemented as the fully differential filter 950.

The differential input 904 comprises the first input node 903A and the second input node 903B, and the differential output 906 comprising the first output node 905A and the second output node 905B. The fully differential filter 950 comprises the fully differential amplifier 902. The fully differential amplifier 902 comprises the non-inverting input node IN+ and the inverting input node IN− coupled to the differential input 904. The fully differential amplifier 902 comprises the non-inverting output node OUT+ and the inverting output node OUT− coupled to the differential output 906. The first feedback network 912A is provided in the first feedback loop 962A and is coupled between the non-inverting output node OUT+ and the inverting input node IN− of the fully differential amplifier 902. The second feedback network 912B is provided in the second feedback loop 962B and is coupled between the inverting output node OUT− and the non-inverting input node IN+ of the fully differential amplifier 902. The common mode voltage is provided at V_{cm} node.

The first input network 908A is coupled between the first input node 903A and the first feedback network 912A. The first output network 910A is coupled between the non-inverting output node OUT+ and the first output node 905A. The second input network 908B is coupled between the second input node 903B and the second feedback network 912B. The second output network 910B is coupled between the inverting output node OUT− and the second output node 905B. In one embodiment, the first input network 908A, the first output network 910A, and the first feedback network 912A are electrically symmetric with the second input network 908B, the second output network 910B, and the second feedback network 912B.

The differential filter 950 comprises two poles and may be realized using the single fully differential amplifier 902. As previously described, the fully differential amplifier 902 comprises a differential input pair comprising the inverting input IN− and the non-inverting IN+ and a corresponding differential output pair comprising the non-inverting output OUT+ and the inverting output OUT−. The fully differential filter 950 comprises the differential input 904 to receive differential input signal V_{id} comprising signal components vᵢₙ, vᵢₚ (e.g., voltage signals 134-1-n, 134-2-n, respectively) at the first and second input nodes 903A, 903B, respectively. The differential filter 950 comprises the differential output 906 to provide filtered differential output signal V_{od} comprising signal components vₒₚ, vₒₙ (e.g., input voltage signals 144-1-n, 144-2-n, respectively) at the first and second output nodes 905A, 905B, respectively.

In one embodiment, the first and second input networks 908A, B may comprise resistors R_{1A, B} coupled to capacitors C_{2A, B}. The first and second feedback networks 912A, B may comprise a resistors R_{2A, B}, R_{3A, B} and capacitors C_{1A, B}. The first and second output networks 910A, B may comprise the resistors R_{4A, B} and capacitors C_{3A, B}.

With respect to the first networks, the first input network 908A may comprise a resistor R_{1A} coupled in series with the first input node 903A. The resistor R_{1A} is coupled to the first feedback network 912A at a node 952A. A capacitor C_{2A} is coupled between the resistor R_{1A} at the node 952A and ground. The first feedback network 912A may comprise a resistor R_{2A} coupled between the non-inverting output OUT+ of the fully differential amplifier 902 and the node 952A. A resistor R_{3A} is coupled to the node 952A and to the inverting input IN− of the fully differential amplifier 902. A capacitor C_{1A} is coupled between the non-inverting output OUT+ and the inverting input IN− of the fully differential amplifier 902. The first output network 910A comprises a resistor R_{4A} coupled between the non-inverting output OUT+ and the first output node 905A. A capacitor C_{3A} is coupled between the first output node 905A and ground.

With respect to the second networks, the second input network 908B may comprise a resistor R_{1B} coupled in series with the second input node 903B. The resistor R_{1B} is coupled to the second feedback network 912B at a node 952B. A capacitor C_{2B} is coupled between the resistor R_{1B} at the node 952B and ground. The second feedback network 912B may comprise a resistor R_{2B} coupled between the non-inverting output OUT+ of the fully differential amplifier 902 and the node 952B. A resistor R_{3B} is coupled to the node 952B and to the inverting input IN− of the fully differential amplifier 902. A capacitor C_{1B} is coupled between the non-inverting output OUT+ and the inverting input IN− of the fully differential amplifier 902. The second output network 910B comprises a resistor R_{4B} coupled between the non-inverting output OUT+ and the second output node 905B. A capacitor C_{3B} is coupled between the second output node 905B and ground.

The capacitors C_{1A, B}, C_{2A. B}, C_{3A, B} and the resistors R_{1A, B}, R_{2A, B}, R_{3A, B}, and R_{4A, B} of the fully differential filter circuit 950 are symmetrically located. In one embodiment, the values of these components may be assumed to be R₁=R_{1A, B}=R_{2A, B}=R_{3A, B}=R_{4A, B}; and C₁=C_{1A}=C_{1B}; C₂=C_{2A}=C_{2B}; and C₃=C_{3A}=C_{3B}. The capacitors C_{1A, B}, C_{2A. B}, C_{3A, B} and the resistors R_{1A, B}, R_{2A, B}, R_{3A, B}, and R_{4A, B} of the fully differential filter circuit 950 are symmetrically located. In one embodiment, the resistors R_{1A, B}, R_{2A, B}, R_{3A, B}, and R_{4A, B} are trimmable. In one embodiment, each of the trimmable resistors R_{1A, B}, R_{2A, B}, R_{3A, B}, and R_{4A, B} may be implemented as the trimmable resistor module 221 coupled to the fully differential amplifier 902. The trimmable resistors R_{1A, B}, R_{2A, B}, R_{3A, B}, and R_{4A, B} may be trimmed on-chip or off-chip. The trimmable resistor module 221 is described below with respect to FIGS. 11A, B, C, D.

In the illustrated embodiment, the values of the components in the first and second input networks 908A, B, first and second output networks 910A, B, and first and second feedback networks 912A, B are assumed to be R₁=R_{1A, B}=R_{2A, B}=R_{3A, B}=R_{4A, B}; and C₁=C_{1A}=C_{1B}; C₂=C_{2A}=C_{2B}; and C₃=C_{3A}=C_{3B}. Accordingly, based on these assumptions, in one embodiment, each of the first and second feedback networks 912A, B may comprise a first resistor (R₁) and a first capacitor (C₁). The first and second input networks 908A, B may comprise the first resistor (R₁) and a second capacitor (C₂). The first and second output networks 910A, B may comprise the first resistor (R₁) and a third capacitor (C₃). Based on these assumptions, the characteristics of the fully differential filter 900 may be defined in terms of the filter transfer function H(s), parameters, e.g., third order Bessel filter parameters, design equations, and components frequency scaling. Several examples of the various characteristics of the fully differential filter 900 are the transfer function:

$$H ( s ) = \frac{{ω}_{n}}{{s}^{2} + \frac{{ω}_{n}}{Q} + {ω}_{n}} \cdot \frac{σ}{s + σ} \qquad ( 31 )$$

In one embodiment, the normalized Bessel third order filter parameters may be selected as: Q=0.691; ωₙ=1.4484 rad/s; σ=1.323 rad/s.

In one embodiment, the design equations may be selected as follows:

$$\begin{matrix}{C}_{1} = \frac{1}{3 {ω}_{n} {R}_{1} Q} & ( 32 ) \\ {C}_{2} = \frac{1}{{ω}_{n} {R}_{1}} & ( 33 ) \\ {C}_{3} = \frac{1}{{R}_{1} σ} & ( 34 )\end{matrix}$$

Component values may be selected as follows: R₁=157 kω, C₁=135 fF; C₂=581 fF; and C₃=307 fF to scale the fully differential filter 900 to approximately 2.5 MHz

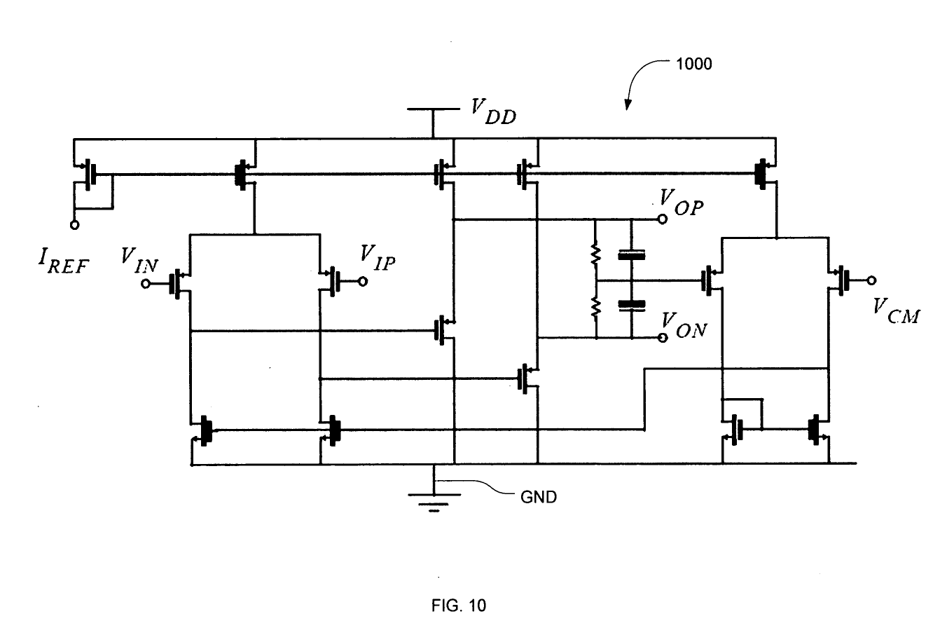

One advantage of the fully differential filter 900 structure over a single-ended structure is that the signal swing is approximately twice as large and, therefore, the larger signal swing increases the S/N ratio. The symmetry of the fully differential filter 950 circuit and the common mode feedback loops cancel out the common mode noise components. Furthermore, the fully differential filter 950 consumes less power because it employs only a single active element, i.e., the fully differential amplifier 902. In one embodiment, the fully differential filter 950 provides a large signal dynamic range suitable for power control. In one embodiment, the fully differential filter 950 circuit reduces quantization and sin (x)/x noise associated with digital amplitude modulation circuits. However, embodiments of the fully differential filter 950 may be employed in other applications where on-chip filtering may be achieved using a similar structure. In one embodiment, the fully differential filter 950 may provide a differential signal structure using a single fully differential amplifier 902 and on-chip RC IC components to realize two poles. In one embodiment, on-chip resistors (R₁) may be trimmed using an automatic trim circuit. In one embodiment, the fully differential amplifier 902 may be formed in a CMOS IC structure as shown in FIG. 10 and described herein below.

In one embodiment, the fully differential filter 950 may be a fully differential active RC third order Bessel filter, for example. The fully differential filter 950 provides differential output signals that are larger (e.g., approximately two times) as compared to single-ended signals and provides an improved signal-to-noise (S/N) ratio. Further, common mode (CM) noise components may be reduced due to the symmetry and CM feedback. The fully differential filter 900 consumes less power as compared to other filter implementations because the fully differential amplifier 902 is the only single active component. Furthermore, the large signal dynamic range of the fully differential filter 900 provides for power control. In one embodiment, the fully differential filter 950 may further comprise an on-chip automatic trimmable resistor module 221 to trim-out components with large variations.

FIG. 10 illustrates one embodiment of a fully differential amplifier 1000. The fully differential amplifier 1000 is one embodiment of the fully differential amplifier 902 used to implement the fully differential filter 950 discussed above with reference to FIG. 9. Characteristics of the fully differential amplifier 1000 may include:

G_{diff}=40 dB PM_{diff}=40°

G_{CM}=90 dB PM_{cm}=73°

The fully differential amplifier 1000 comprises differential voltage input nodes V_{IN} (903A) and V_{IP} (903B). The fully differential amplifier 1000 comprises differential voltage output nodes V_{OP} (905A) and V_{ON} (905B). The fully differential amplifier 1000 comprises a reference current input node I_{REF}. The fully differential amplifier 1000 also comprises supply voltage input node V_{DD} and a ground terminal GND. The common voltage is provided at output node V_{CM}.

FIGS. 11A, 11B, and 11C illustrate three scenarios of one embodiment of a trimmable resistor module 221 as in 1100-1, 1100-2, 1100-3, respectively. The trimmable resistor module 1100-1-3 represent one embodiment of the trimmable resistor module 221 shown in FIG. 2A and may be formed integrally on the same substrate as the baseband processor 202. The trimmable resistor modules 1100-1-3 are described in three separate trimming situations taking into consideration component variations in the fabrication process and temperature dependent component variations. The first trimming module 1100-1 is the case where the value of the reference resistor R_{ref}-1 is just right. The second trimming module 1100-2 is the case where the value of the reference resistor R_{ref}-2 is too small. And the trimming module 1100-3 is the case where the value of the reference resistor R_{ref}-3 is too large.

The trimmable resistor modules 1100-1-3 may comprise up top series connected trim resistors R_{T}-1-p where p is any positive integer. The trim resistors R_{T}-1-p are coupled in series with a base resistor R_{B} and may be bypassed by p logic controlled switches SW-1-p coupled in parallel with the trim resistors R_{T}-1-p. The trim resistors R_{T}-1-p, R_{B}, and R_{ref} are formed of polysilicon (poly) but not limited to polysilicon material only and may be fabricated on the same substrate as the baseband processor 202. The sum of all the series trim resistors R_{T}-1-p and the base resistor R_{B} is the total resistance Rₜₒₜₐₗ measured between a first terminal 1108 and a second terminal 1110. The logic controlled switches SW-1-p are controlled by p comparators 1106-1-p, respectively. The comparators 1106-1-p control the state of the logic controlled switches SW-1-p based on whether an input threshold voltage V_{T} applied to the non-inverting (+) input nodes of the comparator is greater than a reference voltage V_{ref}-1-p applied to the inverting (−) input nodes of the comparator. For example, for any of the comparators 1106-1-p, if the threshold voltage V_{T} is greater than the corresponding reference voltage V_{ref}-1-p, the output of the comparator 1106-1-p is a logic one, which activates (turns on) the corresponding logic controlled switch SW-1-p to a conducting state, and the corresponding trim resistor R_{T}-1-p is bypassed. Conversely, if the threshold voltage V_{T} is less than the corresponding reference voltage V_{ref}-1-p, the output of the comparator 1106-1-p is a logic zero, which deactivates (turns off) the corresponding logic controlled switch SW-1-p to a non-conducting state, and the corresponding trim resistor R_{T}-1-p is located in series with the base resistor R_{B} between the first and second terminals 1108, 1110.

The threshold voltage V_{T} is determined by a precision current source 1104, which drives a trim current Iₜᵣᵢₘ that is proportional to a desired resistance R_{D} value between the first and second terminals 1108, 1110. The precision current source 1104 drives the current Iₜᵣᵢₘ into reference resistors R_{ref}-1-3 to generate the threshold voltage V_{T} where V_{T}=Iₜᵣᵢₘ·R_{ref}. Therefore, the threshold voltage V_{T}-1-3=Iₜᵣᵢₘ·R_{ref}-1-3, respectively are functions of process variations. In one embodiment, the threshold voltages V_{T}-1-3 may be used to compare with precision voltages generated or derived from bandgap voltages 1160-1-3 and 1158 to extraction information on how much the actual resistance are larger or smaller than the nominal value. This information may be used to adjust resistance between the first and second terminals 1108, 1110 to be closer to their desired resistance R_{D}. In one scenario, if all the trim resistors R_{T}-1-p are bypassed, the total resistance measured between the first and second terminals 1108, 1110 is equal to the base resistor R_{B}. The base resistor R_{B} may have a value that is a large percentage of the desired resistance R_{D}. For example, in one embodiment, the base resistor R_{B} may be 70% of the desired resistance R_{D}. The total resistance measured between the first and second terminals 1108, 1110 if all trim resistors R_{T}-1-p are selected in series with the base resistor R_{B} should be greater than the desired resistance R_{D}. The trim resistors R_{T}-1-p may be selected to be about 10-15% of the total resistance Rₜₒₜₐₗ measured between the first and second terminal 1108, 1110. The reference resistor R_{ref}-1-3 are on-chip and physically laid out near the resistors R₁, R₂, R₃ of the filter to achieve similar resistance values. The precision current source 1104 may be derived from the on-chip bandgap reference 132, for example.

FIG. 11D illustrates one embodiment of a precision voltage reference 1150 used to generate the reference voltages V_{ref}-1-p for the trimmable resistor module 1100-1, as illustrated in FIGS. 11A, 11B, and 11C, depicted under three different operating conditions. The precision voltage reference 1150 may be derived from the on-chip bandgap reference 132. The voltage reference 1150 comprises amplifier A₁₁₅₂ coupled to transistor Q₁₁₅₄ and a resistor array 1156 comprising p trim resistors coupled in series. A precision voltage reference V_{REF} is coupled to the non-inverting (+) input node of the amplifier A₁₁₅₂. Accordingly, V_{REF} appears at node 1158. The output of the amplifier A₁₁₅₂ is coupled to the gate of the transistor Q₁₁₅₄. The drain of the transistor is coupled to the node 1158 and the source of the transistor Q₁₁₅₄ is coupled to a supply voltage V_{DD}. Because V_{REF} is a process invariant precision voltage, the voltages at node nodes 1160-3, 1160-2 and 1160-1 of resistor array 1156 are constants as well. This is because the ratios among these resistors are constants, i.e., resistors track each other on the same die, even though the absolute values of individual resistors vary. A fixed voltage is developed across each of the resistors in the based on the values of the desired voltage references V_{ref}-1-p. Accordingly, the voltages developed at the nodes 1160-1-p are used as the reference voltages V_{ref}-1-p, respectively, for the trimmable resistor module 1100-1. In one embodiment, where p=4, the reference voltage at node 1160-1 is approximately 1.6V and corresponds to V_{ref}-1; the reference voltage at node 1160-2 is approximately 1.8V and corresponds to V_{ref}-2; the reference voltage at node 1160-3 is approximately 2.2V and corresponds to V_{ref}-3; and the reference voltage at node 1160-4 is approximately 2.4V and corresponds to V_{ref}-4. It will be appreciated that other reference voltages may be used without limitation.

With reference now back to FIG. 11A, in one embodiment, the trimmable resistor module 1100-1 comprises p=4 series connected trim resistors R_{T}-1-p coupled in series with base resistor R_{B}. The base resistor R_{B}≈70% of the total resistance Rₜₒₜₐₗ; resistor R_{T1}≈20% of the total resistance Rₜₒₜₐₗ; resistor R_{T4}≈10% of the total resistance Rₜₒₜₐₗ; resistor R_{T3}≈10% of the total resistance Rₜₒₜₐₗ; and resistor R_{T4}≈20% of the total resistance Rₜₒₜₐₗ. The voltage reference 1150 supplies the reference voltages V_{ref}-1-p to the inverting (−) input nodes of the respective comparators 1106-1-p. In the embodiment of trimmable resistor module 1100-1, the reference resistor R_{ref-1} is just right, therefore, a threshold voltage V_{T1}≈2.0V is generated based on Iₜᵣᵢₘ and R_{ref-1}, where V_{T1}=Iₜᵣᵢₘ·R_{ref-1}. The threshold voltage V_{T} is applied to the non-inverting (+) input nodes of the comparators 1106-1-p. The threshold voltage V_{T1} of ≈2.0V triggers comparators 1106-1 and 1106-2 and activate logic controlled switches SW-1 and SW-2, respectively. Accordingly, trim resistors R_{T1} and R_{T2} are bypassed (shorted) and the trimmed resistance is given by:
R_{D1}=R_{T4}+R_{T3}+R_{B} (35)

as measured between the first and second terminals 1108, 1110. Because R_{B} is ≈70% of Rₜₒₜₐₗ, R_{T4} is ≈20% of Rₜₒₜₐₗ, and R_{T3} is ≈10% of Rₜₒₜₐₗ, the value of the trimmed resistance R_{D1} is ≈100% of the desired value.

Due to semiconductor process variations, the integrated poly resistor values will vary accordingly. Turning to FIG. 11B, the trimmable resistor module 1100-2 has an R_{ref-2} resistor that is too small. We assume that the value of the R_{ref-2} resistor is undervalued such that the threshold voltage V_{T2}=Iₜᵣᵢₘ·R_{ref-2} is ≈1.75V. In this situation, the threshold voltage V_{T2} triggers only comparator 1106-1 to close logic controlled switch SW-1 and shorts resistor R_{T1} and the trimmed resistance is given by:
R_{D2}=R_{T4}+R_{T3}+R_{T2}+R_{B} (36)

as measured between the first and second terminals 1108, 1110. Because R_{B} is ≈70% of Rₜₒₜₐₗ, R_{T4} is ≈15% of Rₜₒₜₐₗ, R_{T3} is ≈10% of Rₜₒₜₐₗ, and R_{T2} is ≈10% of Rₜₒₜₐₗ, the value of the trimmed resistance R_{D2} is ≈105% of the desired value, or ≈5% too high.

Again, due to semiconductor process variations, the integrated poly resistor values will vary accordingly. Turning to FIG. 11C, the trimmable resistor module 1100-3 has an R_{ref-3} resistor that is too large. We assume that the value of the R_{ref-3} resistor is overvalued such that the threshold voltage V_{T3}=Iₜᵣᵢₘ·R_{ref-3} is ≈2.25V. In this situation, the threshold voltage V_{T3} triggers comparators 1106-1, 1106-2, and 1106-3 to close respective logic controlled switches SW-1, SW-2, and SW-3 and shorts respective trim resistors R_{T1}, R_{T2}, and R_{T3} and the trimmed resistance is given by:
R_{D3}=R_{T4}+R_{B} (37)

as measured between the first and second terminals 1108, 1110. Because R_{B} is ≈70% of Rₜₒₜₐₗ and R_{T4} is ≈15% of Rₜₒₜₐₗ the value of the trimmed resistance R_{D3} is only ≈85% of the desired value, or ≈15% too low.

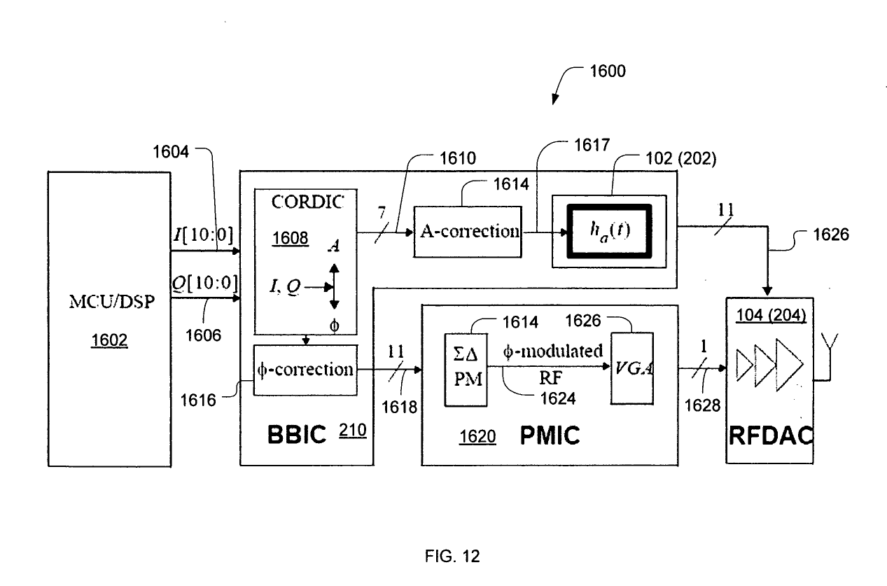

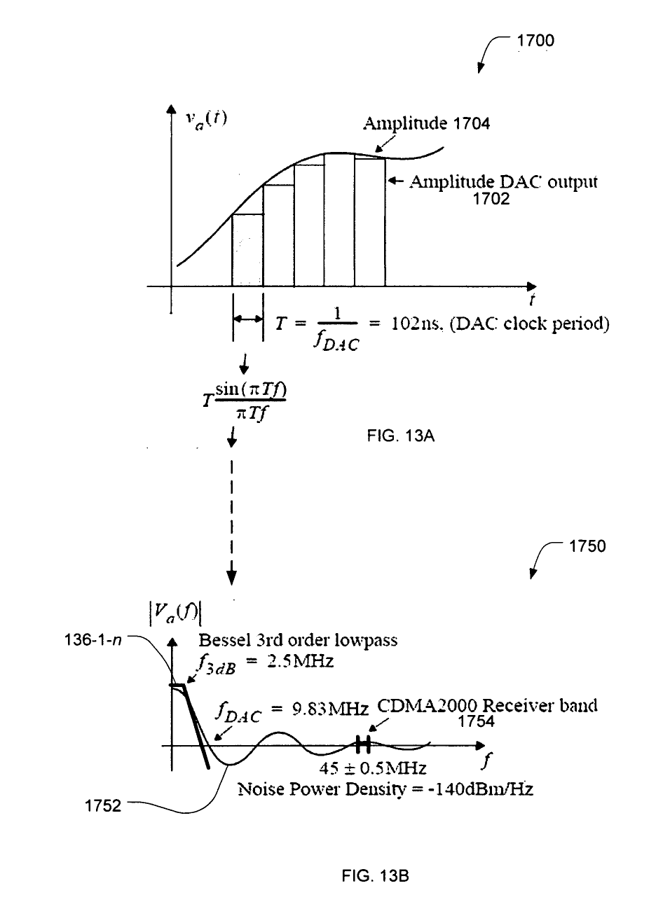

FIG. 12 illustrates one embodiment of a polar modulation power transmitter system comprising one embodiment of the baseband processor in relative relationship to the rest of the polar transmitter system. FIG. 12 illustrates one embodiment of a polar modulation power transmitter system 1600 comprising one embodiment of the baseband processor 102 (202). In one embodiment, the system may comprise a microcontroller unit/digital signal processor 1602 (MCU/DSP) to provide in-phase 1604 (I) and quadrature 1606 (Q) components to a baseband integrated circuit 210 (BBIC). The BBIC 210 may comprise a CORDIC algorithm module 1608 to receive the I 1604 and Q 1606 component inputs and split them into amplitude (A) component 1610 and phase (φ) polar component 1612.

In one embodiment, the CORDIC module 1608 generates a multiple bit digital amplitude component 1610 and provides the amplitude component 1610 to an amplitude correction (A-correction) module 1614. In one embodiment, the digital amplitude component 1610 may comprise seven bits. The output of the A-correction module 1614 is provided to the baseband processor 102 (202) having an impulse response characterized by hₐ(t). The output of the baseband processor 102 (202) is provided to the RF-DAC 104 (204). In one embodiment, the output of the baseband processor 102 (202) may comprise 11 bits, for example.

The CORDIC algorithm module 1608 also provides the phase component 1612 to a phase φ-correction module 1616. The output 1617 of the phase φ-correction module 1616 comprises a multiple bit digital phase φ-correction signal 1618, which in one embodiment may comprise 11 bits, and is provided to a phase modulation integrated circuit 1620 (PMIC). In one embodiment, the PMIC 1620 may comprise, for example, a sigma-delta phase modulator 1622 (ΣΔ PM), which provides a phase φ-modulated RF signal 1624 to a variable gain amplifier (VGA) module 1626. The output 1628 of the VGA module 1626, which in one embodiment may comprise a single bit, is provided to the RF-DAC 104 (204). The output 1626 of the baseband processor 102 (202) is provided to the RF-DAC 104 (204). The system architecture illustrated may provide improved linearity and efficiency. The embodiments are not limited in this context.

FIGS. 13A, 13B illustrate quantization noise associated with a sample-and-hold system and its signal spectrum including the noise at the receive band spectrum. FIGS. 13A, 13B illustrate one embodiment of a sample-and-hold 1700 and signal spectrum 1750 of the multiplexer 116-1-n in one embodiment of the baseband processor 202. FIG. 13A illustrates vₐ(t) as a function of time with vₐ(t) along the vertical axis and time t along the horizontal axis. The multiplexer 116-1-n produces an output signal 1702. The amplitude of the multiplexer 116-1-n output signal 1702 is shown as envelope amplitude 1704.

$$T = \frac{1}{{f}_{DAC}} = 102 ns$$

is the multiplexer 116-1-n clock period.

FIG. 13B illustrates Vₐ(f) 1750, the frequency transform of vₐ(t) in FIG. 13A. Vₐ(f) is shown along the vertical axis and frequency f is shown along the horizontal axis. The frequency f_{DAC}=9.83 MHz, for example. The frequency transform of the multiplexer 116-1-n period

$$T = \frac{1}{{f}_{DAC}} is T \frac{sin ( π Tf )}{π Tf} .$$

The frequency domain output signal 1752 of the multiplexer 116-1-n is filtered by low pass filter 136-1-n. As previously discussed, in one embodiment, the filter 136-1-n may be implemented as a third-order Bessel type low pass filter. In one embodiment, the filter 136-1-n has a 3 dB roll-off at ≈2.5 MHz, for example. As an example, at the CDMA-2000 receiver band 1754 at ≈45±0.5 MHz, the noise power density is ≈−140 dBm/Hz.

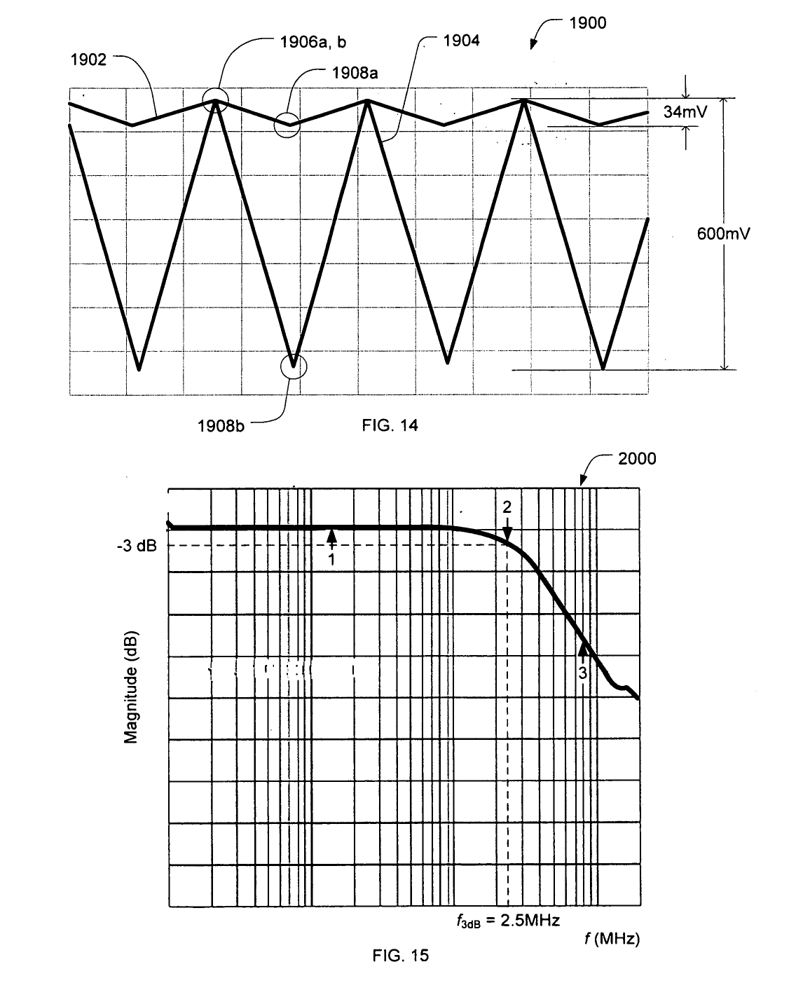

FIG. 14 graphically illustrates measurement result waveforms comprising a first waveform and a second waveform measured at the output of one embodiment of the system baseband processor wherein the amplitude ratio between a first and second waveform illustrates the power control dynamic range. FIG. 14 graphically illustrates measurement result waveforms 1900 comprising a first waveform 1902 and a second waveform 1904 measured at the output of one embodiment of the system 100 baseband processor 102 (202) wherein the amplitude ratio between first and second waveforms 1902, 1904 illustrates the power control dynamic range. The signal dynamic range is 25 dB. The test current trans-resistance is 56 Ohm (current to voltage conversion). Further, the scale for the first waveform is 50 mV/div while the scale for the second waveform is 100 mV/div.

The measurement results illustrate the sum of the single-ended drive current signals 154-1-n of the drivers 138-1-n as the input power control signal 120 is swept with a sawtooth signal at a minimum power level with the bias voltage signals 126-1-n (vₕᵢ₋₁₋ₙ, vₗₒ₋₁₋ₙ) swing ranging vₕᵢ₋ₘᵢₙ-vₗₒ₋ₘᵢₙ and at a maximum power level ranging from vₕᵢ₋ₘₐₓ-vₗₒ₋ₘₐₓ. The first output current waveform 1902 represents the sum of the single-ended drive current signals 154-1-n driven by the drivers 138-1-n when the power control input 120, is set at its minimum power level. The second output current waveform 1904 represents the sum of the single-ended drive current signals 154-1-n driven by the drivers 138-1-n when the power control input 120 is set at its maximum power level. The peaks 1906a, b of the first output current waveform 1902 vₕᵢ₋ₘᵢₙ and the peaks of the second output current waveform 1904 vₕᵢ₋ₘₐₓ are anchored at the same maximum peak level or reference voltage level. The valley 1908a of the first output current waveform 1902 vₕᵢ₋ₘᵢₙ grows within the waveform of the second output current waveform 1904 as the bias voltage signals 126-1-n (vₕᵢ₋₁₋ₙ, vₗₒ₋₁₋ₙ) are increased form vₘᵢₙ to vₘₐₓ until it reaches the valley 1908b of the second output current waveform 1904. The trickle DAC 226 generated voltage signals V_{DACp} and V_{DACm} can shift the first and second waveforms 1902, 1904 up or down.

FIG. 15 graphically illustrates a frequency response waveform 2000 of one embodiment of the Bessel filter implementation of the filter 136-1-n. In the illustrated embodiment, frequency f (MHz) is shown along the horizontal axis and magnitude (dB) is shown along the vertical axis. At marker I, the magnitude response at ≈140 kHz is relatively flat at ≈0.5 dB. At marker 3, the magnitude response at ≈8.0 MHz is at ≈−25 dB. At marker 2, the magnitude response at f_{3 dB}≈2.5 MHz at the target −3 dB point.

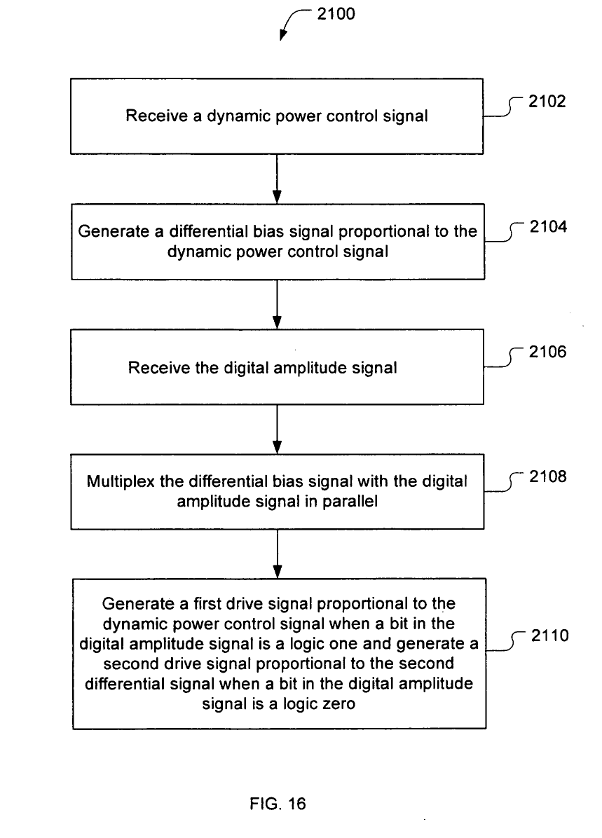

FIG. 16 illustrates one embodiment of a method 2100 to dynamically bias a driver for power control and offset control. The power control module 114 receives 2102 a dynamic power control signal 120. The power control 114 generates 2104 a differential bias signal 126 proportional to the dynamic power control signal 120. The multiplexer 116 receives 2106 the digital amplitude signal 122 after it has been realigned by timing realignment module 118. The multiplexer 116 multiplexes 2108 the differential bias signal with the digital amplitude signal in a bit-wise manner. The driver module 137 generates 2110 a first drive signal proportional to the dynamic power control signal when a bit in the digital amplitude signal is a logic one and generates a second drive signal proportional to the second differential signal when a bit in the digital amplitude signal is a logic zero.

In various other embodiments, the power control module 114 generates a common mode signal V_{cm} and superimposes the differential bias signal 126 on the common mode signal V_{cm}. The trickle DAC 226 of the offset control module 140 generates first and second offset signals V_{DACm}, V_{DACp} and generates a second differential signal 157 based on the differential bias signal 126 and the first and second offset signals V_{DACm}, V_{DACp}. A bias control module 142 generates a bias control signal 148 proportional to a transconductance Gₘ property of a driver module 164. The first drive signal 154 is independent of variations of the transconductance Gₘ property. The bias control module 142 applies the bias control signal 148 to the driver module 137. The bias control module 142 determines a value of current gain (β) of a dummy transistor 156 (Q_{dummy}) in an amplifier RF-DAC 104 generates a bias control 148 signal inversely proportional to the β. A filter 136 filters the differential voltage 126 prior to applying the signal to the driver module 137. The embodiments are not limited in this context.

FIG. 17 illustrates one embodiment of a method 2200 to filter a differential analog signal. The differential filter 900 (950) receives 2202 a differential input signal V_{id} comprising first and second input signal components vᵢₙ, vᵢₚ (e.g., voltage signals 134-1-n, 134-2-n, respectively) at respective first and second input nodes 903A, 903B. The differential input signal V_{id} is coupled 2204 to a differential input of a fully differential amplifier 902. The fully differential amplifier 902 comprises a non-inverting input node IN+ and an inverting input node IN− coupled to the differential input signal V_{id}. A differential output signal V_{od} comprising first and second output signal components vₒₚ, vₒₙ (e.g., input voltage signals 144-1-n, 144-2-n, respectively) is provided 2206 at a differential output of the fully differential amplifier 902 to respective first and second output nodes 905A, 905B. The fully differential amplifier 902 comprises a non-inverting output node OUT+ and an inverting output node OUT− coupled to the differential output signal V_{od}. A first feedback signal is provided 2208 through a first feedback network 912A coupled between the non-inverting output node OUT+ and the inverting input node IN− of the fully differential amplifier 902. A second feedback signal is provided 2210 through a second feedback network 912B coupled between the inverting output node OUT− and the non-inverting input node IN+ of the fully differential amplifier 902.

In various other embodiments, the first input signal component vᵢₙ is received at the first input network 908A coupled between the first input node 903A and the first feedback network 912A. The first output signal component vₒₚ is received at the first output node 905A. The second input signal component vᵢₚ is received at the second input network 908B coupled between the second input node 903B and the second feedback network 912B. The second output signal component vₒₙ is received at the second output node 905B.

A resistor element R in the first and second input networks 908A, B, the first and second output networks 910A, B, or the first and second feedback networks 912A, B may be trimmed. To trim the resistor element R, a threshold voltage is compared to a reference voltage. The resistor is coupled to any one of the first and second input networks 908A, B, the first and second output networks 910A, B, or the first and second feedback networks 912A, B when the threshold voltage V_{T} exceeds the reference voltage V_{ref}. A reference current I_{ref} is driven through a reference resistor to generate the threshold voltage V_{T}.

Numerous specific details have been set forth herein to provide a thorough understanding of the embodiments. It will be understood by those skilled in the art, however, that the embodiments may be practiced without these specific details. In other instances, well-known operations, components and circuits have not been described in detail so as not to obscure the embodiments. It can be appreciated that the specific structural and functional details disclosed herein may be representative and do not necessarily limit the scope of the embodiments.

It is also worthy to note that any reference to “one embodiment” or “an embodiment” means that a particular feature, structure, or characteristic described in connection with the embodiment is included in at least one embodiment. The appearances of the phrase “in one embodiment” in various places in the specification are not necessarily all referring to the same embodiment.

Some embodiments may be implemented using an architecture that may vary in accordance with any number of factors, such as desired computational rate, power levels, heat tolerances, processing cycle budget, input data rates, output data rates, memory resources, data bus speeds and other performance constraints. The embodiments are not limited in this context.

While certain features of the embodiments have been illustrated as described herein, many modifications, substitutions, changes and equivalents will now occur to those skilled in the art. It is therefore to be understood that the appended claims are intended to cover all such modifications and changes as fall within the true spirit of the embodiments.

1. A baseband processor, comprising:
a power control module to receive a dynamic power control signal and to generate a differential bias signal proportional to said dynamic power control signal;
an analog multiplexer to receive a digital amplitude signal comprising n bits and to receive said differential bias signal, said analog multiplexer to multiplex said digital amplitude signal with said differential bias signal in parallel to generate a first differential signal; and
a driver module to receive said first differential signal and to receive a second differential signal and to generate a first drive signal proportional to said dynamic power control signal when a bit in said digital amplitude signal is a logic one and to generate a second drive signal proportional to said second differential signal when a bit in said digital amplitude signal is a logic zero.

2. The baseband processor of claim 1, wherein said first differential signal is proportional to said dynamic power control signal.

3. The baseband processor of claim 1, wherein said power control module is to generate a common mode signal and wherein said differential bias signal is complementary and superimposed on said common mode signal.

4. The baseband processor of claim 1, further comprising an offset control module coupled to said driver module, said offset control module to receive said differential bias signal and to receive first and second offset signals, said offset control module to generate said second differential signal based on said differential bias signal and said first and second offset signals.

5. The baseband processor of claim 4, wherein said differential bias signal comprises first and second components, wherein said second differential signal comprises third and fourth components, and wherein said third component comprises said first component and said first offset signal and wherein said fourth component comprises said second component and said second offset signal.

6. The baseband processor of claim 4, further comprising a digital-to-analog converter to generate said first and second offset signals.

7. The baseband processor of claim 1, further comprising a bias control module coupled to said driver module, said bias control module to generate a bias control signal to bias said driver module, wherein said bias control signal is proportional to a transconductance property of said driver module, and wherein said drive signal is independent of variations of said transconductance property.

8. The baseband processor of claim 7, wherein said bias control module is to determine a value of current gain (β) of a transistor in an amplifier, and wherein said bias control signal is proportional to the inverse of said β, and wherein said drive signal is proportional to the inverse of said β.

9. The baseband processor of claim 1, wherein said analog multiplexer and said driver module comprise a differential signal processing topology.

10. The baseband processor of claim 1, further comprising a filter coupled between said analog multiplexer and said driver module.

11. A polar modulation transmitter system, comprising:
an amplifier comprising at least a first and second transistor, said first and second transistors are formed on the same substrate and have similar current gains (β); and
a baseband processor to dynamically bias a driver module coupled to said amplifier, said baseband processor comprising:
a power control module to receive a dynamic power control signal and to generate a differential bias signal proportional to said dynamic power control signal; and
an analog multiplexer to receive a digital amplitude signal comprising n bits and to receive said differential bias signal, said analog multiplexer to multiplex said digital amplitude signal with said differential bias signal in parallel to generate a first differential signal;
wherein said driver module is coupled to at said least first transistor, said driver module to receive said first differential signal and to receive a second differential signal and to generate a first drive signal to drive said at least first transistor, said drive signal proportional to said dynamic power control signal, when a bit in said digital amplitude signal is a logic one and to generate a second drive signal to drive said at least first transistor, said second drive signal proportional to said second differential signal, when a bit in said digital amplitude signal is a logic zero.

12. The system of claim 11, wherein said first differential signal is proportional to said dynamic power control signal.

13. The system of claim 11, further comprising an offset control module coupled to said driver module, said offset control module to receive said differential bias signal and to receive first and second offset signals, said offset control module to generate said second differential signal based on said differential bias signal and said first and second offset signals.

14. The system of claim 11, wherein said differential bias signal comprises first and second components, wherein said second differential signal comprises third and fourth components, and wherein said third component comprises said first component and said first offset signal and wherein said fourth component comprises said second component and said second offset signal.

15. The system of claim 11, further comprising a bias control module coupled to said driver module, said bias control module to generate a bias control signal to bias said driver module, wherein said bias control signal is proportional to a transconductance property of said driver module, and wherein said first and second drive signals are independent of variations of said transconductance property.

16. The system of claim 15, wherein said bias control module is to determine a value of current gain (β) of said at least second transistor, and wherein said bias control signal is proportional to the inverse of said β, and wherein said first and second drive signals are proportional to the inverse of said β.

17. A method to dynamically bias a driver for power control and offset control, the method comprising:
receiving a dynamic power control signal;
generating a differential bias signal proportional to said dynamic power control signal;
receiving a digital amplitude signal;
multiplexing said differential bias signal with said digital amplitude signal in parallel; and
generating a first drive signal proportional to said dynamic power control signal when a bit in said digital amplitude signal is a logic one and generating a second drive signal proportional to said second differential signal when a bit in said digital amplitude signal is a logic zero.

18. The method of claim 17, comprising:
generating a common mode signal; and
superimposing said differential bias signal on said common mode signal.

19. The method of claim 17, comprising:
generating first and second offset signals; and
generating a second differential signal based on said differential bias signal and said first and second offset signals.

20. The method of claim 17, comprising:
generating a bias control signal proportional to a transconductance property of a driver module, wherein said first drive signal is independent of variations of said transconductance property; and
applying said bias control signal to said driver module.

21. The method of claim 20, comprising:
determining a value of current gain (β) of a transistor in an amplifier; and
generating a bias control signal inversely proportional to said β.

22. The method of claim 17, comprising:
filtering said first drive signal.
